(19) United States
(12) Patent Application Publication
(10) Pub. No.: US 2026/0066794 A1
(43) Pub. Date: Mar. 5, 2026

(54) POWER MODULE FOR TRANS-INDUCTOR VOLTAGE REGULATOR

(71) Applicant: Monolithic Power Systems, Inc., Kirkland, WA (US)

(72) Inventors: Zhe Yang, San Jose, CA (US); Ting Ge, San Jose, CA (US); Yishi Su, Hangzhou, Zhejiang (CN)

(21) Appl. No.: 19/385,444

(22) Filed: Nov. 11, 2025

Related U.S. Application Data
(63) Continuation-in-part of application No. 18/469,800, filed on Sep. 19, 2023.

(51) Int. Cl. H02M 3/158; H01F 27/24; H01F 27/28

(52) U.S. Cl. CPC H02M 3/158; H01F 27/24; H01F 27/28

(57) ABSTRACT

A power module comprises a device layer and an inductor assembly. The device layer has a first surface, an opposite second surface, and two pairs of switches. The inductor assembly, whose second surface attaches to the device layer’s first surface, has a magnetic core, a first winding, a second winding, a third winding, and a fourth winding. These windings are at least partially embedded in the magnetic core and expose ends on the second surface of the inductor assembly. The first and third windings and the magnetic core form a first transformer, and the second and fourth windings and the magnetic core form a second transformer. The third and fourth windings are electrically connected in series. The first and second windings each have a horizontal section parallel to the inductor assembly’s first surface, while the third and fourth windings are under these horizontal sections.

### CROSS-REFERENCE TO RELATED APPLICATIONS

The present application is a continuation-in-part of U.S. Application No. 18/469,800 filed on Sept. 19, 2023, which is incorporated herein by reference in its entirety.

### BACKGROUND OF THE INVENTION

### 1. Field of the Invention

The present invention relates generally to electronic components, and more particularly but not exclusively to power modules.

### 2. Description of Related Art

A trans-inductor voltage regulator (TLVR) is a type of voltage regulator that uses a winding of a transformer as an output inductor. The transformer, referred to as a TLVR transformer, has a trans-inductor on one side and an output inductor on the other side. In a multiphase TLVR, the output inductors may be connected in parallel to generate the output voltage, and the trans-inductors may be connected in series. Because of the series connection of the trans-inductors, all of the phases can respond to a change in load current, allowing for a faster transient response compared to a conventional voltage regulator.

A TLVR provides a reduced physical footprint compared to a conventional multiphase voltage regulator and maintains high efficiency across a wide range of load conditions. These attributes make the TLVR well-suited for powering high-performance processors and accelerators used in data centers, high-performance computing systems, and artificial intelligence applications, where rapid load changes and high power density are common. However, with the requirements of small-size power supply apparatus and increasing performance demands in these and other applications, there remains a continuing need to improve TLVR designs.

### SUMMARY OF THE INVENTION

It is an object of the present invention to provide a power module for trans-inductor voltage regulator (TLVR).

Embodiments of the present invention are directed to a power module comprising a device layer and an inductor assembly. The device layer has a first surface and an opposite second surface. The device layer comprises a first power die and a second power die, and each of the first power die and the second power die has a pair of switches electrically connected in series. The inductor assembly has a first surface and an opposite second surface, wherein the second surface of the inductor assembly is attached to the first surface of the device layer. The inductor assembly comprises a magnetic core, a first winding, a second winding, a third winding, and a fourth winding. The first winding, the second winding, the third winding, and the fourth winding are at least partially embedded within the magnetic core and each have a first end and a second end exposed at the second surface of the inductor assembly. The third winding and the first winding are magnetically coupled through at least partial of the magnetic core to form a first transformer, the fourth winding and the second winding are magnetically coupled through at least partial of the magnetic core to form a second transformer, and the third winding and the fourth winding are electrically connected in series. Each of the first winding and the second winding comprises a horizontal section substantially parallel to the first surface of the inductor assembly, and the third winding and the fourth winding are respectively positioned under the horizontal sections of the first winding and the second winding.

Embodiments of the present invention are directed to a power module comprising a device layer and an inductor assembly. The device layer has a first surface and an opposite second surface. The device layer comprises a first pair of switches electrically connected in series and a second pair of switches electrically connected in series. The inductor assembly has a first surface and an opposite second surface, wherein the second surface of the inductor assembly is attached to the first surface of the device layer. The inductor assembly comprises a magnetic core, a first heat sink layer, a second heat sink, a first winding, a second winding, a third winding, and a fourth winding. The first heat sink layer and the second heat sink layer wrap at least partial of the magnetic core. The first winding, the second winding, the third winding, and the fourth winding are at least partially embedded within the magnetic core and each have a first end and a second end exposed at the second surface of the inductor assembly. The first end of the first winding is electrically connected to a common node of the first pair of switches, and the first end of the second winding is electrically connected to a common node of the second pair of switches. The third winding and the first winding are magnetically coupled through at least partial of the magnetic core to form a first transformer, the fourth winding and the second winding are magnetically coupled through at least partial of the magnetic core to form a second transformer, and the third winding and the fourth winding are electrically connected in series. The first winding surrounds the third winding, and the second winding surrounds the fourth winding.

Embodiments of the present invention are directed to an inductor assembly comprising a magnetic core, a first winding, a second winding, a third winding, and a fourth winding. The first winding, the second winding, the third winding, and the fourth winding are at least partially embedded within the magnetic core and each have a first end and a second end exposed at a bottom surface of the inductor assembly. The first winding and the third winding are respectively configured as a primary winding and a secondary winding of a first transformer, and the second winding and the fourth winding are respectively configured as a primary winding and a secondary winding of a second transformer. Each of the first winding and the second winding comprises a horizontal section substantially parallel to the bottom surface of the inductor assembly, and the third winding and the fourth winding are respectively disposed under the horizontal sections of the first winding and the second winding.

These and other features of the present invention will be readily apparent to persons of ordinary skills in the art upon reading the entirety of this disclosure, which includes the accompanying drawings and claims.

### BRIEF DESCRIPTION OF THE DRAWINGS

The present invention can be further understood with reference to following detailed description and appended drawings, wherein like elements are provided with like reference numerals. These drawings are only for illustration purpose, thus may only show part of the devices and are not necessarily drawn to scale.

FIG. 1 schematically shows a prior art multi-phase power converter 10 which comprises a controller 101, N power devices 103 and N inductors L for supplying power to a load 104.

FIG. 2 shows a power module 20 for a dual-phase power converter in accordance with an embodiment of the present invention.

FIG. 3 shows a disassembled and perspective view illustrating the power module 20 of FIG. 1.

FIG. 4 shows a cross sectional view illustrating the power module 20 taken along AA’ line of FIG. 1 in accordance with an embodiment of the present invention.

FIG. 5 shows a bottom view of the inductor assembly 203 in accordance with an embodiment of the present invention.

FIG. 6 shows a top view of the device substrate 202 in accordance with an embodiment of the present invention.

FIG. 7 shows a bottom view of the device substrate 202 in accordance with an embodiment of the present invention.

FIG. 8 shows a bottom view of the bottom substrate 201 in accordance with an embodiment of the present invention.

FIG. 9 is a side view illustrating a system 90 employing the power module 20 in accordance with an embodiment of the present invention.

FIG. 10 shows a circuit diagram of a multi-phase trans-inductor voltage regulator (TLVR) 30 in accordance with an embodiment of the present invention.

FIG. 11 schematically shows a circuit 40 of a power module for a dual-phase TLVR in accordance with an embodiment of the present invention.

FIG. 12 shows a power module 40A implementing the circuit 40 of FIG. 11 in accordance with an embodiment of the present invention.

FIG. 13 shows a disassembled and perspective view illustrating the power module 40 of FIG. 12.

FIG. 14 shows a 3D perspective view of primary windings L1 and L2 and secondary windings TL1 and TL2 in accordance with an embodiment of the present invention.

FIG. 15 show a top view and a bottom view of an inductor assembly 403A in accordance with an embodiment of the present invention.

FIG. 16 shows a 3D perspective view of primary windings L1B and L2B and the secondary windings TL1 and TL2 in accordance with another embodiment of the present invention.

FIG. 17 shows a top view of a device substrate 402A in accordance with an embodiment of the present invention.

FIG. 18 shows a bottom view of the device substrate 402A in accordance with an embodiment of the present invention.

FIG. 19 shows a disassembled and perspective view of a power module 40B for the circuit 40 of FIG. 11 in accordance with another embodiment of the present invention.

FIG. 20 shows a 3D perspective view and a top perspective view of the secondary windings TL1 and TL2 in accordance with an embodiment of the present invention.

FIG. 21 shows a top perspective view and a bottom view of an inductor assembly 403B in accordance with an embodiment of the present invention.

FIG. 22 illustrates a process for forming ends of the windings of the inductor assembly 403B of FIG. 21 in accordance with an embodiment of the present invention.

FIG. 23 shows a top view of a device substrate 402B in accordance with an embodiment of the present invention.

FIG. 24 shows a bottom view of the device substrate 402B of FIG. 23 in accordance with an embodiment of the present invention.

FIG. 25 shows a cross-sectional view illustrating the power module 40B taken along BB’ line of FIG. 19 in accordance with an embodiment of the present invention.

FIG. 26 shows a bottom view of a bottom substrate 401B in accordance with an embodiment of the present invention.

FIG. 27 schematically shows electrical connection paths of the secondary windings TL1 and TL2.

### DETAILED DESCRIPTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms "left",” right", "in", "out", "front", "back", "up", "down", "top", "atop", "bottom", “on”, "over", "under", "above", "below", “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

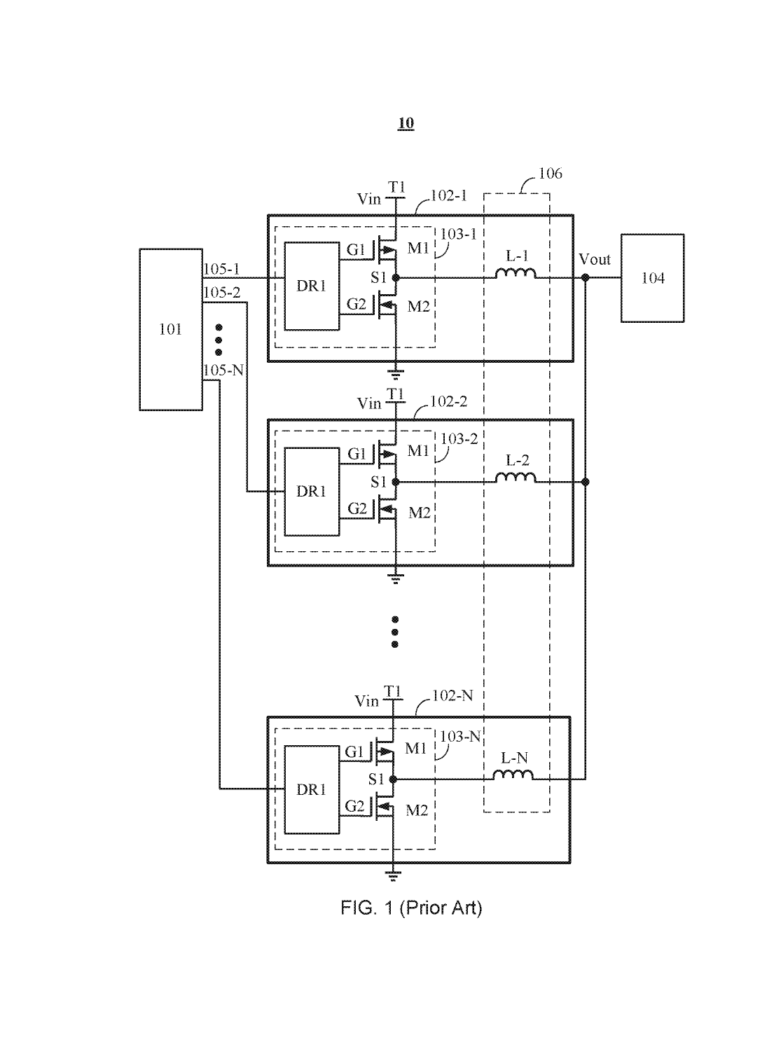

FIG. 1 schematically shows a prior art multi-phase power converter 10 which comprises a controller 101, N power blocks 103-1~103-N and N inductors L-1~L-N for supplying power to a load 104, wherein N is an integer, and N≥1. Each power block 103 and one inductor L represent one power stage, i.e., one phase 102 of the power converter 10, as shown in FIG. 1. Each power block 103 includes switches M1, M2 and a driver DR1 for providing driving signals G1 and G2 to drive the switches M1 and M2 respectively. The controller 101 provides N phase control signals 105-1~105-N respectively to N power blocks 103-1~103-N to control the N phases 102-1~102-N working out of phase, i.e., each one of the inductors L-1~L-N sequentially absorb power from the input source and sequentially deliver power to the load 104. It should be noticed that the outputs of all phases as shown in FIG. 1 are connected to work as a multi-phase converter. However, each phase output may be separated to work as multiple independent converters which could have different output voltage levels for different load demands.

The power stage 102 with Buck topology is shown in FIG. 1 for example. Persons of ordinary skill in the art should appreciate that power stages with other topologies, like Boost topology, Buck-Boost topology could also be adopted in a multi-phase power converter.

The inductors L-1~L-N could be implemented by one or a few coupled inductors or could be implemented by N single inductors.

When N=2, the multi-phase power converter 10 is used as a dual-phase power converter or two separate single-phase converters. For the ease of description, dual-phase power module for a dual-phase power converter is discussed as an example to illustrate the present invention.

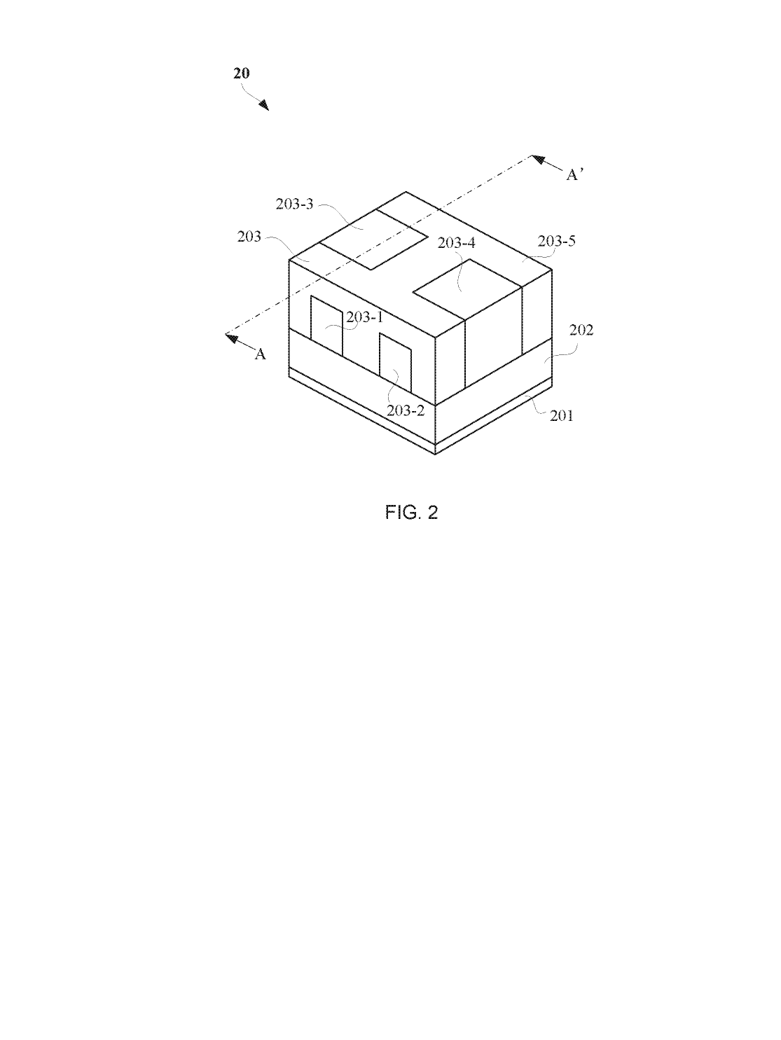

FIG. 2 shows a power module 20 for a dual-phase power converter in accordance with an embodiment of the present invention. The power module 20 may serve as the power stage 102 of FIG. 1, with N=2. The power module 20 includes a bottom substrate 201, a device substrate 202 and an inductor assembly 203. The bottom substrate 201 is arranged at the bottom of the power module 20. The device substrate 202 is arranged on the bottom substrate 201. The inductor assembly 203 is arranged on the device substrate 202. Power device chips integrating the components of the power blocks 103 shown in FIG. 1 is embedded within the device substrate 202. The inductors L are integrated in the inductor assembly 203.

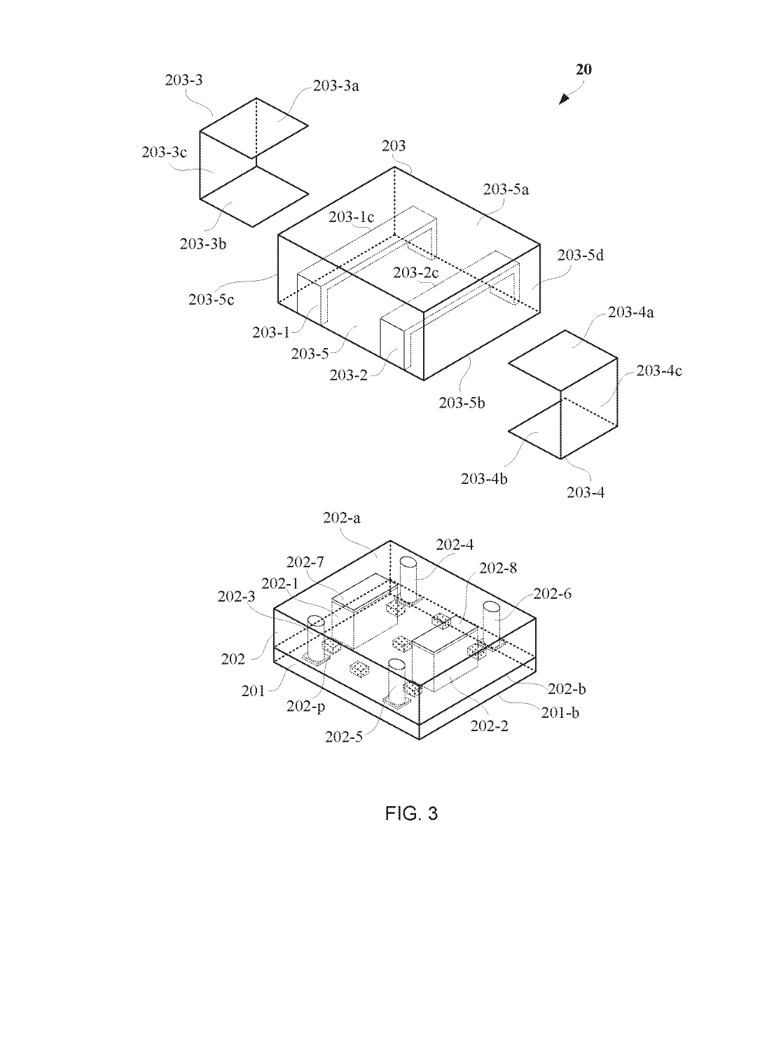

FIG. 3 shows a disassembled and perspective view illustrating the power module 20 of FIG. 2. As shown in FIG. 3, the device substrate 202 includes a first power device chip 202-1, a second power device chip 202-2, a first pair of connecting pillars 202-3 and 202-4, a second pair of connecting pillars 202-5 and 202-6, and a plurality of discrete components 202-p embedded within the device substrate 202. Each one of the first power device chip 202-1 and the second power device chip 202-2 integrates one power block 103 in FIG. 1, which includes the switches M1, M2, the driver DR1, and further integrates some auxiliary circuits not shown in FIG. 1. The first pair of the connecting pillars includes a first connecting pillar 202-3 and a second connecting pillar 202-4 arranged at opposite sides of the first power device chip 202-1. The second pair of the connecting pillars includes a third connecting pillar 202-5 and a fourth connecting pillar 202-6 arranged at opposite sides of the second power device chip 202-2. Each one of the connecting pillars has a first end connecting out of the device substrate 202, and connected to the corresponding winding of the inductor assembly 203, and a second end connected to the bottom substrate 201. The connecting pillars shown in the example of FIG. 3 are cylinders. It should be appreciated that any shape of the connecting pillars is applicable to the present invention. The discrete components 202-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 3, the inductor assembly 203 includes a magnetic core 203-5, a first winding 203-1 and a second winding 203-2 passing through the magnetic core 203-5. The first winding 203-1 and the magnetic core 203-5 form a first inductor L-1 as shown in FIG. 1. The second winding 203-2 and the magnetic core 203-5 form a second inductor L-2 as shown in FIG. 1. Furthermore, the inductor assembly 203 includes a first heat sink layer 203-3 and a second heat sink layer 203-4, each of which has a “C” shape, and partially wraps the magnetic core 203-5. As can be seen from FIG. 3, the first heat sink layer 203-3 has a first portion 203-3a partially covering a first surface 203-5a of the magnetic core 203-5, a second portion 203-3b partially covering a second surface 203-5b of the magnetic core 203-5, and a third portion 203-3c connecting the first portion 203-3a and the second portion 203-3b, and partially covering a third surface 203-5c of the magnetic core 203-5, wherein the first surface 203-5a and the second surface 203-5b are opposite, and the third surface 203-5c is vertical to the first surface 203-5a and the second surface 203-5b. The second heat sink layer 203-4 has a first portion 203-4a partially covering the first surface 203-5a, a second portion 203-4b partially covering the second surface 203-5b, and a third portion 203-4c connecting the first portion 203-4a and the second portion 203-4b, and covering a fourth surface 203-5d of the magnetic core 203-5, wherein the fourth surface 203-5d is opposite to the third surface 203-5c, and is vertical to the first surface 203-5a and the second surface 203-5b of the magnetic core 203-5. The surfaces of the magnetic core 203-5 are also referred as surfaces of the inductor module 203. It should be appreciated that the first heat sink layer 203-3 and the second heat sink layer 203-4 are configured for transferring heat from the power device chips to the environment or external components. The shape of the first heat sink layer 203-3 and the second heat sink layer 203-4 may be varying in different applications, e.g., the first heat sink layer 203-3 may have a “L” shape with the second portion 203-3b and the third portion 203-3c, and similarly, the second heat sink layer 203-4 may have a “L” shape with the second portion 203-4b and the third portion 203-4c.

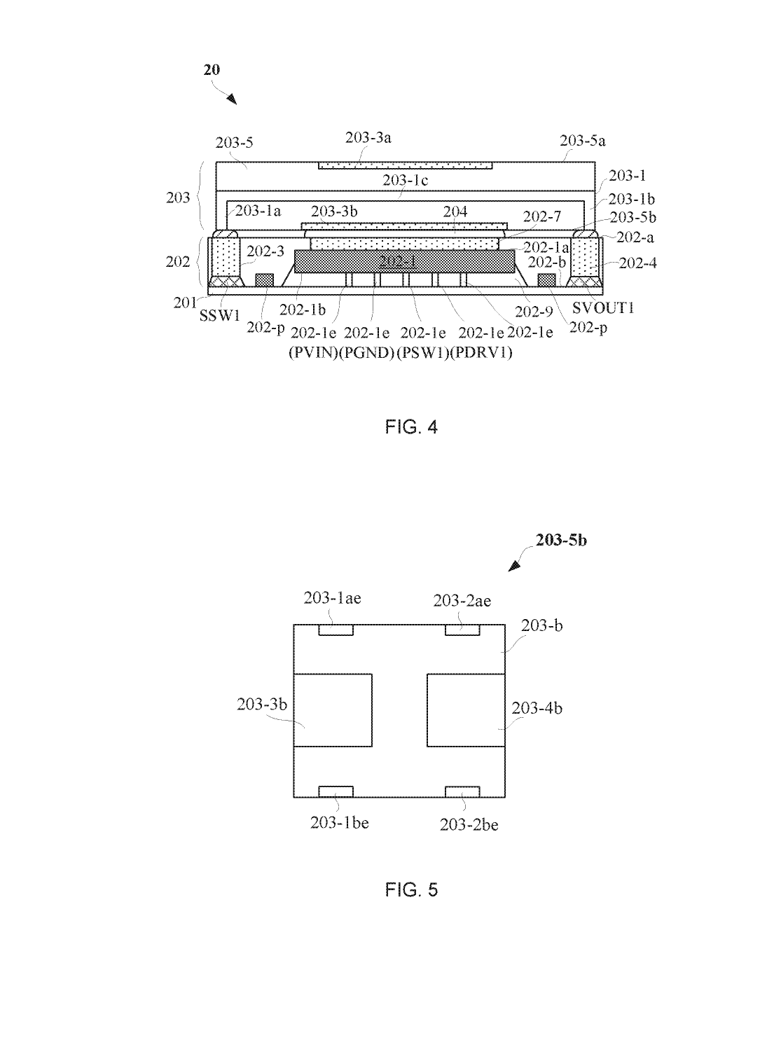

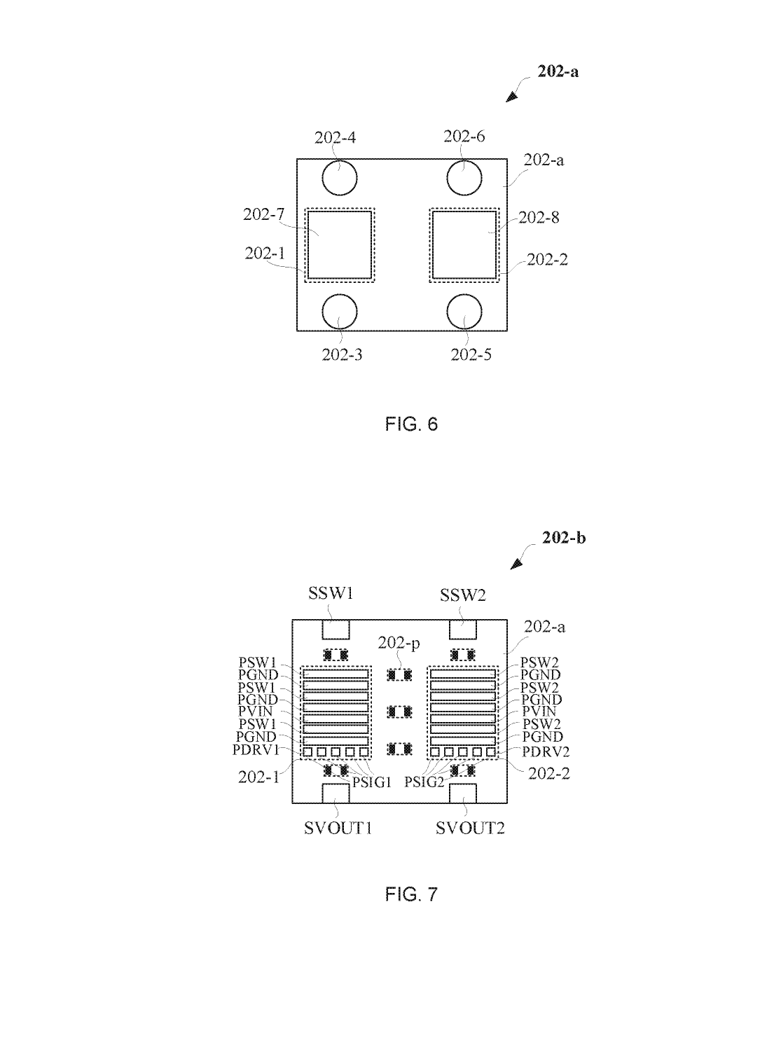

FIG. 4 shows a cross-sectional view illustrating the power module 20 taken along AA’ line of FIG. 2 in accordance with an embodiment of the present invention. FIG. 5 shows a bottom view of the inductor assembly 203, i.e., the second surface 203-5b of the inductor assembly 203, in accordance with an embodiment of the present invention. FIG. 6 shows a top view of the device substrate 202, i.e., the first surface 202-a of the device substrate 202, in accordance with an embodiment of the present invention. FIG. 7 shows a bottom view of the device substrate 202, i.e., the second surface 202-b of the device substrate 202, in accordance with an embodiment of the present invention. The structure of the power module 20 will be illustrated with reference to FIGS. 3~7.

As shown in FIG. 4, the first power device chip 202-1 has a first surface 202-1a and a second surface 202-1b. The first surface 202-1a is covered by a top heat layer 202-7 as shown in FIGS. 4 and 6, and the second surface 202-1b has a plurality of pins 202-1e (including pins PVIN, PGND, PSW1, PDRV1, and etc.) exposed on the second surface 202-b of the device substrate 202 as shown in FIGS. 4 and 7, and connected to the bottom substrate 201. Similarly, The first surface 202-2a of the second power device chip 202-2 is covered by a top heat layer 202-8 as shown in FIG. 6, and the second surface 202-2b of the second power device chip 202-2 has a plurality of pins 202-2e (including pins PVIN, PGND, PSW2, PDRV2, and etc.) exposed on the second surface 202-b of the device substrate 202 as shown in FIG. 7, and connected to the bottom substrate 201. It should be appreciated that the pins shown in FIGS. 4 and 7 are for illustration purpose. More pins may be configured in a real application. Furthermore, the pin shape, the pin size and the pin distribution would be varying in different applications. The top heat layer 202-7 and the top heat layer 202-8 are heat disposal layers, which are made of copper in one embodiment, and are made of other material in other embodiments. Persons of ordinary skill in the art should appreciate that any suitable layer configured to transfer heat from the power device chip is applicable as the top heat layer. In one embodiment, the first portion 203-3a of the first heat sink layer 203-3 and the first portion 203-4a of the second heat sink layer 203-4 are extending to each other and merged as one piece. In one embodiment, the second portion 203-3b of the first heat sink layer 203-3 and the second portion 203-4b of the second heat sink layer 203-4 are extending to each other and merged as one piece. In one embodiment, the first portion 203-3a of the first heat sink layer 203-3 and the first portion 203-4a of the second heat sink layer 203-4 are removed, and a heat radiator may remove heat from the first power device chip 202-1 and the second power device chip 202-2 via the third portion 203-3c of the first heat sink layer 203-3 and the third portion 203-4c of the second heat sink layer 203-4. Similarly, the top heat layer 202-7 and the top heat layer 202-8 could be merged as a whole piece.

As mentioned before, the first power device chip 202-1 integrates the switches M1, M2, the driver DR1 shown in FIG. 1, and other accessory circuits not shown in FIG. 1. The plurality of pins 202-1e of the first power device chip 202-1 includes at least an input pin PVIN, a switching pin PSW1, a ground pin PGND, and a driving pin PDRV1 as shown in FIG. 7. The first switch M1 has a first terminal coupled to the input pin PVIN (corresponding to the input terminal T1 in FIG. 1) to receive the input voltage Vin (shown in FIG. 1), a second terminal connected to the switching pin PSW1 (corresponding to the switching terminal S1 in FIG. 1), and a control terminal configured to receive a first driving signal G1. The second switch M2 has a first terminal connected to the switching pin PSW1, a second terminal connected to the ground pin PGND, and a control terminal configured to receive a second driving signal G2. The driver DR1 is coupled to the driving pin PDRV1 to receive a phase control signal 105, and to provide the first driving signal G1 and the second driving signal G2 based on the phase control signal 105. The plurality of pins of the power device chips 202-1 and 202-2 are electrically connected to external circuits/devices/components via the bottom substrate 201. The bottom substrate 201 may be attached to a mainboard where the load (CPU, GPU, etc.) located, and there may be circuits/devices/components on the mainboard providing the input voltage Vin, the phase control signal 105, and a ground reference GND that provides a common ground for the first power device chip 202-1 and the second power device chip 202-2 via the ground pins PGND.

It should be appreciated that the second power device chip 202-2 has the same structure as the first power device chip 202-1, and is not discussed for the brevity of description.

The first winding 203-1 and the second winding 203-2 are embedded in the magnetic core 203-5 and have an upside-down “U” shape, and are parallel to each other. In the example shown in FIG. 4, the first winding 203-1 has a first portion 203-1a and a second portion 203-1b having ends 203-1ae and 203-1be connected out of the second surface 203-5b of the magnetic core 203-5, and has a middle portion 203-1c parallel to the first surface 203-5a of the magnetic core 203-5 and connecting the first portion 203-1a and the second portion 203-1b. The end 203-1ae of the first portion 203-1a of the first winding 203-1 connects out of the second surface 203-5b of the magnetic core 203-5 as shown in FIG. 5, and is electrically connected to the first connecting pillar 202-3 embedded within the device substrate 202 by soldering or other connecting means as shown in FIG. 4. The end 203-1be of the second portion 203-1b of the first winding 203-1 connects out of the second surface 203-5b of the magnetic core 203-5 as shown in FIG. 5, and is electrically connected to the second connecting pillar 202-4 embedded within the device substrate 202 by soldering or other connecting means as shown in FIG. 4. It should be appreciated that the second winding 203-2 has the similar structure with the first winding 203-1 as shown in FIG. 3, and has two ends 203-2ae and 203-2be electrically connected to third connecting pillar 202-5 and the fourth connecting pillar 202-6 respectively.

The second portion 203-3b of the first heat sink layer 203-3 partially covers the second surface 203-5b of the magnetic core 203-5 as shown in FIG. 5, and is attached to the top heat layer 202-7 directly or via a heat conductive contact 204 as shown in the example of FIG. 4. Similarly, the second portion 203-4b of the second heat sink layer 203-4 partially covers the second surface 203-5b of the magnetic core 203-5 as shown in FIG. 5, and is attached to a top heat layer on top of the second power device chip 202-2 directly or via a heat conductive contact. In one embodiment, the heat sink layers 203-3 and 203-4 are made of copper, and dissipate heat from the top heat layers on top of the power device chips 202-1 and 202-2. Consequently, the heat of the power device chips 202-1 and 202-2 are dissipated via the top heat layers 202-7 and 202-8 and the heat sink layer 203-3 and 203-4, respectively. The heat sinks 203-3 and 203-4 are attached to the magnetic core 203-5 by either thermal glue, thermal paste, or direct contact.

The first connecting pillar 202-3 has one end connecting out of the first surface 202-a of the device substrate 202 as shown in FIG. 6, and connected to the end of the first portion 203-1a of the first winding 203-1 as shown in FIG. 4, and has the other end connected to the bottom substrate 201 via a first switching terminal SSW1. Furthermore, the end of the first portion 203-1a of the first winding 203-1, and the first connecting pillar 202-3, are electrically connected to the switching pin PSW1 of the first power device chip 202-1 via conductive traces inside the bottom substrate 201. Consequently, the heat of the first power device chip 202-1 is further dissipated through the first connecting pillar 202-3 and the first winding 203-1. The second connecting pillar 202-4 has one end connecting out of the first surface 202-a of the device substrate 202 and connected to the end of the second portion 203-1b of the first winding 203-1, and has the other end connected to the bottom substrate 201 via a first output voltage terminal SVOUT1. The third connecting pillar 202-5 has one end connecting out of the first surface 202-a of the device substrate 202 as shown in FIG. 6, and connected to the end 203-2ae of the first portion 203-2a of the second winding 203-2 shown in FIG. 5, and has the other end connected to the bottom substrate 201 via a second switching terminal SSW2. The end 203-2ae of the first portion 203-2a of the second winding 203-2, and the third connecting pillar 202-5, are electrically connected to the switching pin PSW2 of the second power device chip 202-2 via conductive traces inside the bottom substrate 201. Consequently, the heat of the second power device chip 202-2 is further dissipated through the third connecting pillar 202-5 and the second winding 203-2. The fourth connecting pillar 202-6 has one end connecting out of the first surface 202-a of the device substrate 202 and connected to the end 203-2be of the second portion 203-2b of the second winding 203-2, and has the other end connected to the bottom substrate 201 via a second output voltage terminal SVOUT2. In some embodiments of the present invention, the connecting pillars 202-3~202-6 are soldered to the bottom substrate 201, and the first switching terminal SSW1, the first output voltage terminal SVOUT1, the second switching terminal SSW2 and the second output voltage terminal SVOUT2 are solder pastes at the ends of the connecting pillars 202-3~202-6. It should be appreciated that the connecting pillars 202-3~202-6 may be connected to the bottom substrate 201 directly, or by other connecting means known in the art, e.g., the connecting pillars 202-3~202-6 may be protruded out of the bottom surface 202-b of the device substrate 202, and are inserted to grooves of the bottom substrate 201.

As shown in FIG. 7, the first power device chip 202-1 has signal pins PSIG1 which may be configured to transmit temperature monitoring signal, current monitoring signal, and other necessary signals for communicating between the first power device chip 202-1 and external circuits. The second power device chip 202-2 has signal pins PSIG2 which may be configured to transmit temperature monitoring signal, current monitoring signal, and other necessary signals for communicating between the second power device chip 202-2 and external circuits. In FIG. 7, the driving pin PDRV1 is illustrated as an example of signal pins PSIG1, and the driving pin PDRV2 is illustrated as an example of signal pins PSIG2. Other signal pins, like the pins for transmitting the temperature monitoring signal, the current monitoring signal, etc., are not specifically labeled for brevity. The discrete components 202-p together with the power device chips 202-1 and 202-2 which are molded within the device substrate 202 have connecting terminals on the second surface of the device substrate 202. As shown in the embodiment of FIG. 7, each one of the discrete components 202-p, i.e., the capacitors and the resistors, has two pins or pads exposed on the second surface 202-b of device substrate 202, and connected to the bottom substrate 201, wherein the discrete components 202-p are electrically connected to the power device chips 202-1, 202-2, and external components/circuits via the bottom substrate 201. Persons of ordinary skill in the art should know that the pins shown in FIG. 7 are for illustrating, which should not be limiting the present invention. The pin distribution on the second surface of the device substrate 202 is determined by the requirement of the application specs, and is varying in different applications.

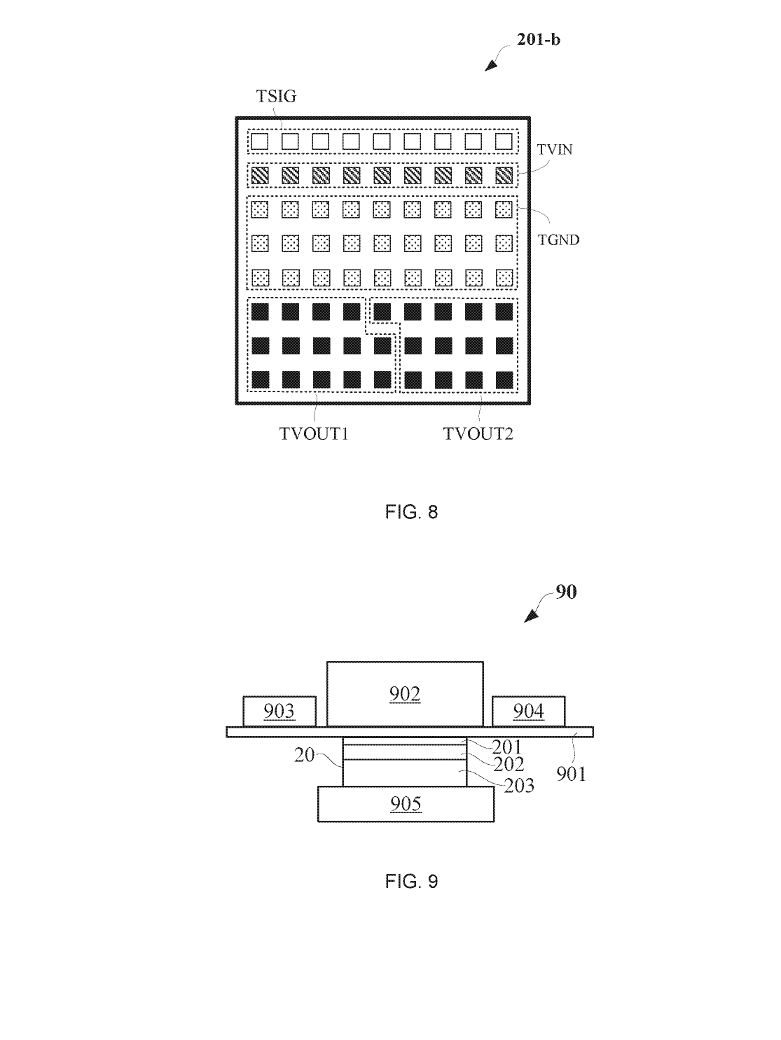

FIG. 8 shows a bottom view of the bottom substrate 201, i.e., the second surface 201-b of the bottom substrate 201, in accordance with an embodiment of the present invention. The second surface 201-b of the bottom substrate 201 includes a signal pad area TSIG, an input pad area TVIN, a ground pad area TGND, a first output voltage pad area TVOUT1 and a second output voltage pad area TVOUT2. Each one of the pad areas includes a plurality of pads. The pads on the second surface 201-b of the bottom substrate 201 connect through to the first surface 201-a of the bottom substrate 201 using, e.g., vias and conductive traces inside the bottom substrate 201. The plurality of pads of the signal pad area TSIG are electrically connected to the signal pins PSIG1 of the first power device chip 202-1 and the signal pins PSIG2 of the second power device chip 202-2 respectively, like the driving pins PDRV1, PDRV2, temperature monitoring pins, etc. The plurality of pads of the input pad area TVIN are electrically connected to the input pins PVIN of the first power device chip 202-1 and the second power device chip 202-2. The plurality of pads of the ground pad area TGND are electrically connected to the ground pins PGND of the first power device chip 202-1 and the second power device chip 202-2. The plurality of pads of the first output voltage pad area TVOUT1 are electrically connected to the end of the second portion 203-1b of the first winding 203-1 via the second connecting pillar 202-4. The plurality of pads of the second output voltage pad area TVOUT2 are electrically connected to the end of the second portion 203-2b of the second winding 203-2 via the fourth connecting pillar 202-6. In one embodiment, the pads of the first output voltage pad area TVOUT1 and the pads of the second output voltage pad area TVOUT2 are electrically disconnected, which makes the power module 20 work as two independent converters. In some embodiments, the pads of the first output voltage pad area TVOUT1 and the pads of the second output voltage pad area TVOUT2 are electrically connected by external conductive traces or traces inside the bottom substrate, which makes the power module 20 work as a dual-phase power converter.

In the present invention, by stacking the bottom substrate 201, the device substrate 202 and the inductor assembly 203 vertically, the power density is increased. The first portions and the second portions of the first winding and the second winding are exposed to the side surfaces of the magnetic core as shown in the embodiments of the present invention. It should be appreciated that the first portions and the second portions of the first winding and the second winding could be totally embedded inside the magnetic core, thereby switching noise is shielded by the magnetic core 205 and the device substrate 202 of the power module 20, thus better noise immunity is provided compared to the prior art power modules.

In the present invention, the power device chips embedded within the device substrate dissipate heat from the top, i.e., through the top heat layers, and meanwhile from the bottom, i.e., through the pins attached to the bottom substrate, and then further through the windings and magnetic core of the inductor assembly, which makes the heat dissipation performance excellent.

In one embodiment, the device substrate 202 is formed by firstly attaching the power device chips 202-1 and 202-2, the discrete components 202-p, and the connecting pillars 202-3~202-6 to the bottom substrate 201, and secondly molding all the aforementioned components together. The power module 20 could be produced by stacking the inductor module 203 on top (first surface 202-a) of the device substrate 202, which highly eases the manufacturability and improves the robustness.

It should be appreciated that the device substrate 202 could also be implemented by other means, e.g., by PCB (Printed Circuit Board) process. Specifically, the power device chips 202-1 and 202-2, the discrete components 202-p, and the connecting pillars 202-3~202-6 could be integrated in a PCB or be embedded by several PCB layers.

In one embodiment, the bottom substrate 201 is implemented by a PCB layer.

FIG. 9 is a side view illustrating a system 90 employing the power module 20 in accordance with an embodiment of the present invention. The system 90 includes a mainboard 901, a load 902, external components 903, 904, the power module 20, and a heat radiator 905. In the embodiment of FIG. 9, the load 902 and the power module 20 are attached to the opposite surfaces of the mainboard 901, which shorts the power delivery path, and improves the power efficiency. The load 902 may be a CPU, a GPU, or any other microprocessors. The power module 20 is attached to the mainboard 901 by the bottom substrate 201. The top of the power module 20 is covered by the heat radiator 905 for heat dissipation. The external components 903 and 904 may be the devices providing power, i.e., the input voltage Vin, or providing the phase control signals 105, to the power module 20. In other embodiments, the power module 20 and the load 902 may be placed on the same surface of the mainboard 901.

The power module for the dual-phase power converter is described for illustrating the present invention. It should be appreciated that the power module in the present invention could be scaled in by including a single power device chip and a single inductor to implement a single-phase power converter, or be scaled out by including more power device chips and inductors to implement multiple power converters or a multi-phase power converter.

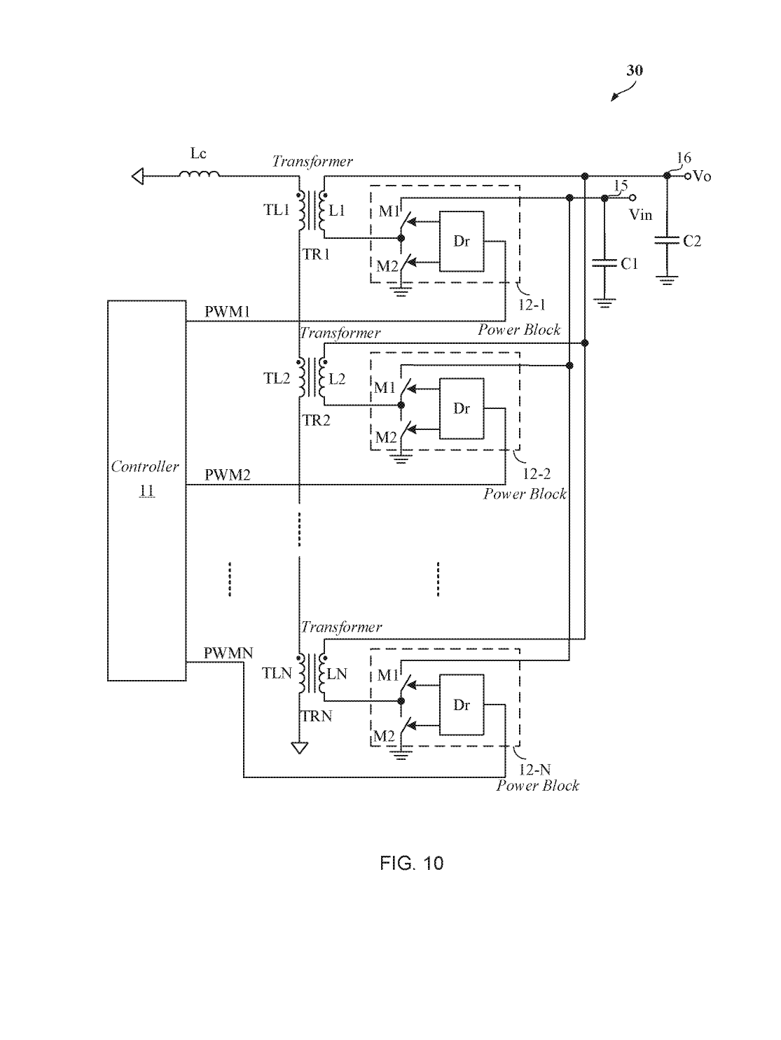

FIG. 10 shows a circuit diagram of a multi-phase trans-inductor voltage regulator (TLVR) 30 in accordance with an embodiment of the present invention. In the present disclosure, unless otherwise noted, connections described with reference to schematic diagrams and nodes are electrical connections. The TLVR 30 has a plurality of power blocks 12 (including 12-1 - 12-N) and a plurality of transformers TR (including TR1 - TRN), wherein N is an integer, and N>1. Each power block 12-i (i = 1 - N) has a pair of switches M1 and M2, and a driver Dr for driving the switches M1 and M2. In each phase of the TLVR 30, the switches M1 and M2 each have a first terminal, a second terminal, and a control terminal. The first terminal of the switch M1 is connected to an input terminal 15 to receive an input voltage Vin, the second terminal of the switch M1 is connected to the first terminal of the switch M2 to form a switch node, and the second terminal of the switch M2 is connected to a primary‑side ground. The control terminals of the switches M1 and M2 respectively receive a driving signal from the driver Dr. The switches M1 and M2 are turned on and off by the driver Dr alternatively. The driving signals of the switches M1 and M2 may be in phase or out of phase, depending on the types of the switch M1 and M2. In one embodiment, the TLVR 30 further comprises a controller 11. The controller 11 provides a plurality of control signals PWM1 - PWMN respectively to the corresponding power block 12. The driver Dr of each power block 12 receives the corresponding control signal PWM and converts the control signal PWM to suitable driving signals for driving the switches M1 and M2. It should be noted that the outputs of all phases as shown in FIG. 10 are connected to work as a multi-phase converter. However, each phase output may be separate and independent, and the TLVR 30 thus could work as multiple independent converters which could have different output voltage levels for different load demands.

In FIG. 10, each power block 12-i (i=1, 2, …, N) and the corresponding transformer TRi form one phase of the multi-phase TLVR 30. As shown in FIG. 10, each transformer TRi (i=1, 2, …, N) has a primary winding Li which works as an output inductor and further has a secondary winding TLi. Each primary winding Li (i=1, 2, …, N) is connected between the corresponding power block 12-i and an output terminal 16 which provides the output voltage Vo, and all the secondary windings TL1-TLN are connected in series. The TLVR 30 further has a compensation inductor Lc for suppressing output current ripple and improving system efficiency. In one embodiment, the compensation inductor Lc is connected in series with all the secondary windings TL1-TLN to form a trans-inductor loop. The compensation inductor Lc is optional, and in some examples, the compensation inductor Lc could be eliminated by a controlled leakage inductance between the primary winding Li (i=1, 2, …, N) and the secondary winding TLi of each phase, thus the secondary windings TL1-TLN form the trans-inductor loop. Such an elimination of the compensation inductor Lc may allow for significant amounts of additional space and an increased power density on the power module with TLVR technology.

In the embodiment of FIG. 10, the TLVR 30 further comprises an input capacitor C1 connected between the input terminal 15 and the primary‑side ground, and an output capacitor C2 connected between the output terminal 16 and the primary‑side ground. In some embodiments, each of the input capacitor C1 and the output capacitor C2 may be implemented by a plurality of discrete capacitors coupled in parallel. In the present disclosure, N could be any suitable number as required. In some embodiments, N=2, and then the TLVR 30 is used as a dual-phase power converter or two independent single-phase converters.

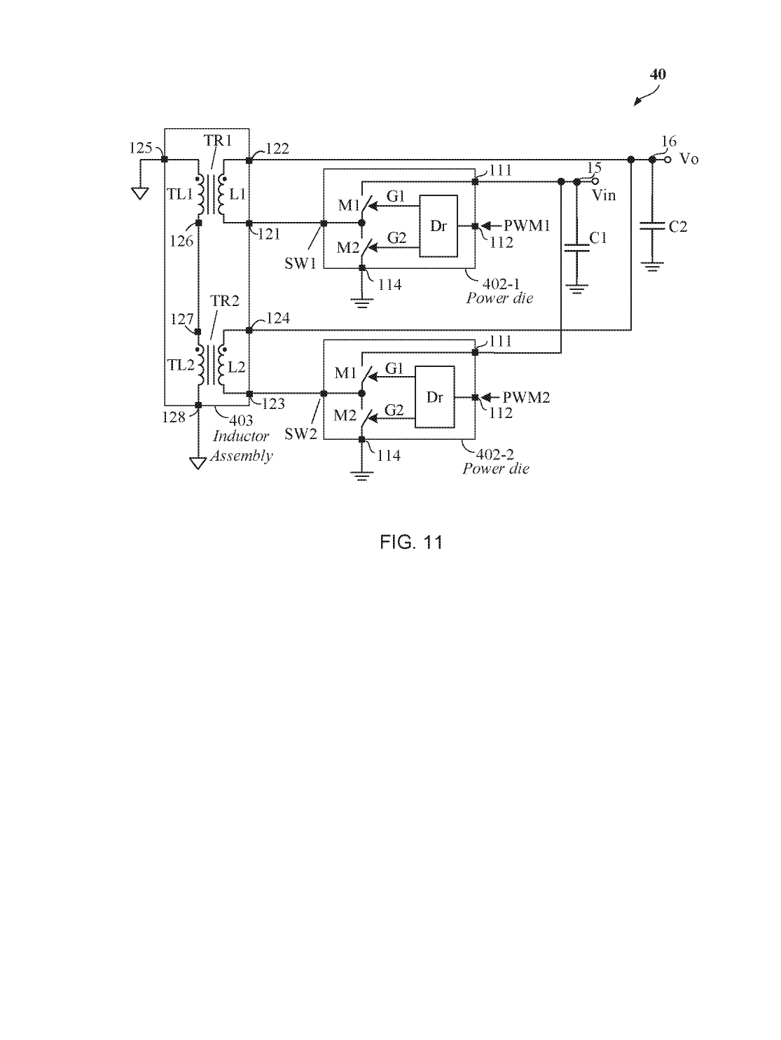

FIG. 11 schematically shows a circuit 40 of a power module for a dual-phase TLVR in accordance with an embodiment of the present invention. In the embodiment of FIG. 11, the power module has an inductor assembly 403A which implements the transformers TR1 and TR2, a power die 402-1 which implements the power block 12-1 of FIG. 10, and a power die 402-2 which implements the power block 12-2 of FIG. 10. In the embodiment of FIG. 11, each power block 12 is implemented by one power die 402, i.e., one power die 402 integrates the pair of switches of one phase. While in another embodiment, both the power blocks 402-1 and 402-2 are integrated into one power die, i.e., the power module may have only one power die. In yet another embodiment, the switches M1 and M2 of the power block 402-1 are respectively integrated in two power dies and the switches M1 and M2 of the power block 402-2 are respectively integrated into two power dies, i.e., the power module may have four power dies. As shown in FIG. 11, each of the power dies 402-1 and 402-2 has an input node 111 electrically connected to the input terminal 15 to receive the input voltage Vin, a control node 112 configured to receive the control signal PWM (i.e., PWM1, PWM2), a switch node SW (i.e., SW1, SW2) formed by the pair of switches M1 and M2, and a reference node 114 electrically connected to the reference ground. The primary winding L1 and the power die 402-1 form a first phase of switching circuit, and the primary winding L2 and the power die 402-2 form a second phase of switching circuit. Each phase of the switching circuits receives the input voltage Vin to generate the output voltage Vo, via the corresponding power die (i.e., 402-1, 402-2), and the corresponding primary winding (i.e., L1, L2). In the example of FIG. 11, each of the switching circuits is a buck circuit. As can be appreciated, each of the switching circuits may also be configured as boost circuit or other types of switching circuit depending on the application.

Furthermore, in FIG. 11, the primary winding L1 has a first end 121 electrically connected to the switch node SW1 (i.e., a common node of the switches M1 and M2 of the power die 402-1), and a second end 122 electrically connected to the output terminal 16. The primary winding L2 has a first end 123 electrically connected to the switch node SW2 (i.e., a common node of the switches M1 and M2 of the power die 402-2), and a second end 124 electrically connected to the output terminal 16. The secondary winding TL1 has a first end 125 electrically connected to a secondary‑side ground, and a second end 126. The secondary winding TL2 has a first end 127 electrically connected to the second end 126 of the secondary winding TL1, and a second end 128 electrically connected to the secondary‑side ground. In another embodiment, one of the first end 125 of the secondary winding TL1 and the second end 128 of the secondary winding TL2 may also be electrically connected to an external compensation inductor. In one embodiment, a primary side and a secondary side of the power module circuit 40 are electrically isolated from one another, so that the secondary‑side ground and the primary‑side ground are also isolated. In other embodiments, the primary side and the secondary side of the power module circuit 40 may also be non-isolated, e.g., one of the first end 125 of the secondary winding TL1 and the second end 128 of the secondary winding TL2 may be connected to the primary side of the power module circuit 40.

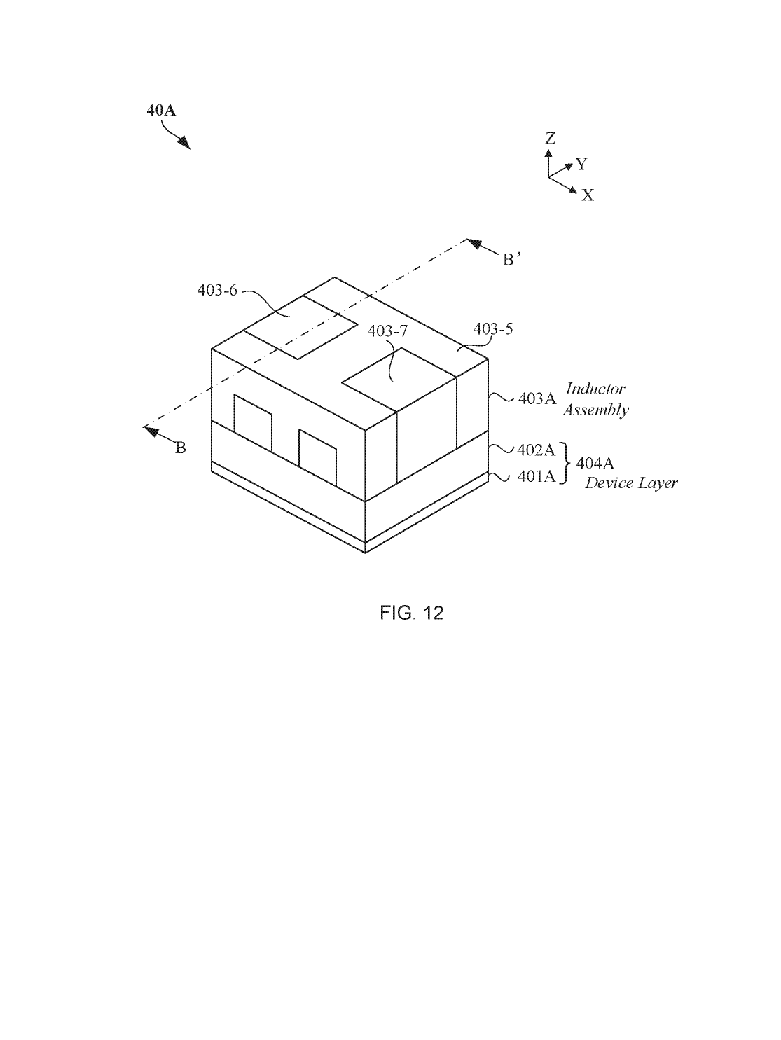

FIG. 12 shows a power module 40A in accordance with an embodiment of the present invention implementing the circuit 40 of FIG. 11. As shown in FIG. 12, the power module 40A has a bottom substrate 401A, a device substrate 402A and the inductor assembly 403A. The bottom substrate 401A is arranged at the bottom of the power module 40. The device substrate 402A is arranged on the bottom substrate 401A. The inductor assembly 403A is arranged on the device substrate 402A. The power dies 402-1 and 402-2 shown in FIG. 11 are at least partially embedded within the device substrate 402A. In one embodiment, the power dies 402-1 and 402-2 and other necessary components are disposed on the bottom substrate 401A and then encapsulated with molding material to form the device substrate 402A, and the device substrate 402A and the bottom substrate 401A form a device layer 404A. The transformers TR are integrated into the inductor assembly 403A. In the example of FIG. 12, the inductor assembly 403A further comprises heat sink layers 403-6 and 403-7 for heat dissipation of the power module 40A.

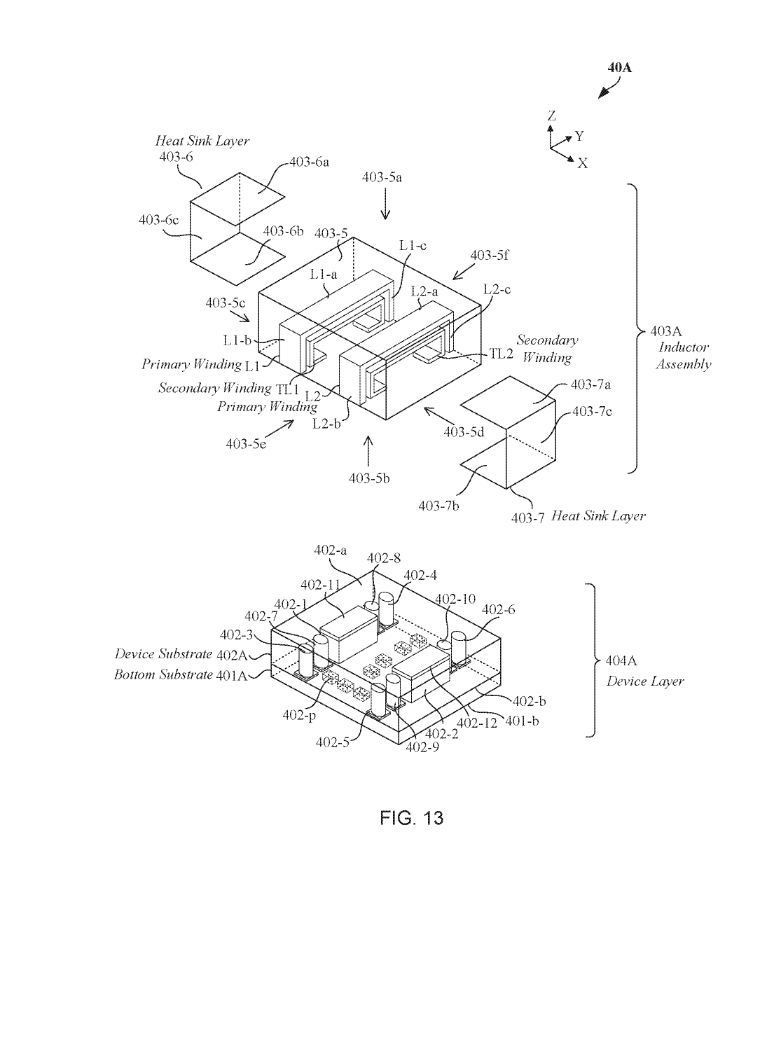

FIG. 13 shows a disassembled and perspective view illustrating the power module 40A of FIG. 12. As shown in FIG. 13, the device substrate 402A includes the power die 402-1, the power die 402-2, connecting pillars 402-3 through 402-10, and a plurality of passive components 402-p, wherein all these components are at least partially embedded within the device substrate 402A. Each of the power die 402-1 and the power die 402-2 integrates one power block 12 in FIG. 10, which includes the switches M1, M2, the driver Dr, and further integrates some auxiliary circuits not shown in FIG. 10. In another embodiment, each of the power die 402-1 and the power die 402-2 may only integrate the switches M1 and M2, and each driver Dr is implemented by a separate driver IC (not shown in FIG. 13). As shown in FIG. 13, the device substrate 402A has a upper surface 402-a and a lower surface 402-b opposite to the upper surface 402-a. In one embodiment, the power die 402-1, the power die 402-2, the connecting pillars 402-5 through 402-10, and the plurality of passive components 402-p are soldered to the bottom substrate 401A and then encapsulated with molding material to form the device substrate 402A. It should be noted that not all of the passive devices 402-p are labeled in FIG. 13 for clarity of illustration, and the layout of all the components in the device substrate 402A is not limited by the example shown in FIG. 13.

In the embodiment of FIG. 13, the device substrate 402A further comprises a die heat sink 402-11 and a die heat sink 402-12 to dissipate heat produced by the power dies 402-1 and 402-2. The die heat sink 402-11 covers at least partial of the power die 402-1, and the die heat sink 402-12 covers at least partial of the power die 402-2. Each of the die heat sinks 402-11 and 402-12 has a surface exposed at the upper surface 402-a of the device substrate 402A, wherein the upper surface 402-a is also an upper surface of the device layer 404A. The die heat sinks 402-11 and 402-12 are optional, and in some embodiments, the die heat sinks 402-11 and 402-12 may also be omitted. Each of the connecting pillars 402-3 through 402-10 has a first end exposed at the upper surface 402-a of the device layer 404A to connect with the inductor assembly 403A and has a second end exposed at the lower surface 402-b of the device substrate 402A to connect with the bottom substrate 401A. The connecting pillars 402-3 through 402-10 shown in the example of FIG. 13 are cylinders, and it should be appreciated that any shape of the connecting pillars is applicable to the present disclosure. The passive components 402-p comprise resistors and capacitors of the circuits of the power module 40, like a first plurality of capacitors for implementing the input capacitor C1, a second plurality of capacitors for implementing the output capacitor C2, and filter capacitors and resistors for the drivers 13 and internal logic circuits power supplies (not shown in FIG. 11), etc. It should be noted that not all of the passive components 402-p are labeled in FIG. 13 for clarity of illustration, and the layout of all the components disposed in the device substrate 402A is not limited by the example shown in FIG.13.

In the example of FIG. 13, the inductor assembly 403A comprises the two primary windings L1 and L2, the two secondary windings TL1 and TL2, and a magnetic core 403-5. The magnetic core 403-5 has an upper surface 403-5a and a lower surface 403-5b which opposite each other, side surfaces 403-5c and 403-5d which opposite each other and perpendicular to the upper surface 403-5a and the lower surface 403-5b, and side surfaces 403-5e and 403-5f which opposite each other and perpendicular to the upper surface 403-5a and the lower surface 403-5b. In the example of FIG. 13, the primary windings L1 and L2 and the secondary windings TL1 and TL2 are at least partially embedded in the magnetic core 403-5, and the surfaces of the magnetic core 403-5 are also referred to as surfaces of the inductor assembly 403A. In the embodiment of FIG. 13, the ends 121-128 of the windings L1, L2, TL1 and TL2 are exposed at the lower surface 403-5b of the inductor assembly 403A, and each end is attached to the corresponding connecting pillar of the device substrate 402A, which will be further illustrated in FIG. 15. The magnetic core 403-5 is made of at least one kind of magnetic material. In one embodiment, the magnetic core 403-5 is one-piece and made of powder iron or any other suitable magnetic material. As shown in FIG. 13, the primary winding L1 and the primary winding L2 pass through the magnetic core 403-5 and are substantially parallel with each other, and the secondary windings TL1 and TL2 are also substantially parallel with each other. In the embodiments of the present disclosure, “substantially parallel” refers to that two or more elements are oriented such that they are within a tolerance of 5 degrees of being perfectly parallel. In the embodiment of FIG. 13, the primary winding L1 and the secondary winding TL1 are magnetically coupled via at least partial of the magnetic core 403-5 to form the transformer TR1 of FIG. 11, and the primary winding L2 and the secondary winding TL2 are magnetically coupled via at least partial of the magnetic core 403-5 to form the transformer TR2 of FIG. 11.

As shown in FIG. 13, the primary winding L1 and primary winding L2 have an "n" shape, with each extending towards the top surface 311 of the inductor assembly 30. The primary winding L1 has a horizontal section L1-a and two vertical sections L1-b and L1-c, wherein the horizontal section L1-a connects the vertical sections L1-b and L1-c, and the vertical sections L1-b and L1-c are perpendicular to the horizontal section L1-a. Similarly, the primary winding L2 has a horizontal section L2-a and two vertical sections L2-b and L2-c, wherein the horizontal section L2-a connects the vertical sections L1-b and L2-c, and the vertical sections L2-b and L2-c are perpendicular to the horizontal section L2-a. The horizontal sections L1-a and L2-a are substantially parallel to the upper surface 403-5a of the inductor assembly 403A, i.e., top surfaces of the primary windings L1 and L2 are substantially parallel to the upper surface 403-5a of the inductor assembly 403A. In the embodiment of FIG. 13, the primary winding L1 surrounds the secondary winding TL1, and the primary winding L2 surrounds the secondary winding TL2. To be specific, the secondary winding TL1 is disposed under the horizontal section L1-a of the primary winding L1 and between the two vertical sections L1-b and L1-c of the primary winding L1, and the secondary winding TL2 is disposed under the horizontal section L2-a of the primary winding L2 and between the two vertical sections L2-b and L2-c of the primary winding L2. The secondary winding TL1 and the secondary winding TL2 each have a main body which is also an "n" shape, wherein the main body also has a horizontal section and two vertical sections as the primary windings L1 and L2 do. In one embodiment, the primary windings L1 and L2 and the secondary windings TL1 and TL2 are made of copper.

Furthermore, each of the heat sink layers 403-6 and 403-7 has a “C” shape and wraps at least partial of the magnetic core 403-5. As can be seen from FIG. 13, the heat sink layer 403-6 has a portion 403-6a covering at least partial of a upper surface 403-5a of the magnetic core 403-5, a portion 403-6b covering at least partial of a lower surface 403-5b of the magnetic core 403-5, and a portion 403-6c connecting the portions 403-6a and 403-6b and covering at least partial of the side surface 403-5c of the magnetic core 403-5. The heat sink layer 403-7 has a portion 403-7a covering at least partial of the upper surface 403-5a of the magnetic core 403-5, a portion 403-7b covering at least partial of the lower surface 403-5b of the magnetic core 403-5, and a portion 403-7c connecting the portions 403-7a and 403-7b, and covering at least partial of the side surface 403-5d of the magnetic core 403-5. The shapes of the heat sink layers 403-6 and 403-7 may be varying in different applications, e.g., the heat sink layer 403-6 may have a “L” shape with the portion 403-6b and the portion 403-6c, and similarly, the heat sink layer 403-7 may have a “L” shape with the portion 403-7b and the portion 403-7c. In one embodiment, the heat sink layers 403-6 and 403-7 are made of copper. In the embodiment of FIG. 13, when the device layer 404A and the inductor assembly 303 are assembled together, the portion 403-6b of the heat sink layer 403-6 is attached to the upper surface 402-a of the device layer 404A covering at least partial of the die heat sink 402-11, and the portion 403-7b of the heat sink layer 403-7 is attached to the upper surface 402-a of the device layer 404A covering at least partial of the die heat sink 402-12. Therefore, heat of the device layer 404A is dissipated upwards via the die heat sinks 402-11 and 402-12, and the heat sink layers 403-6 and 403-7.

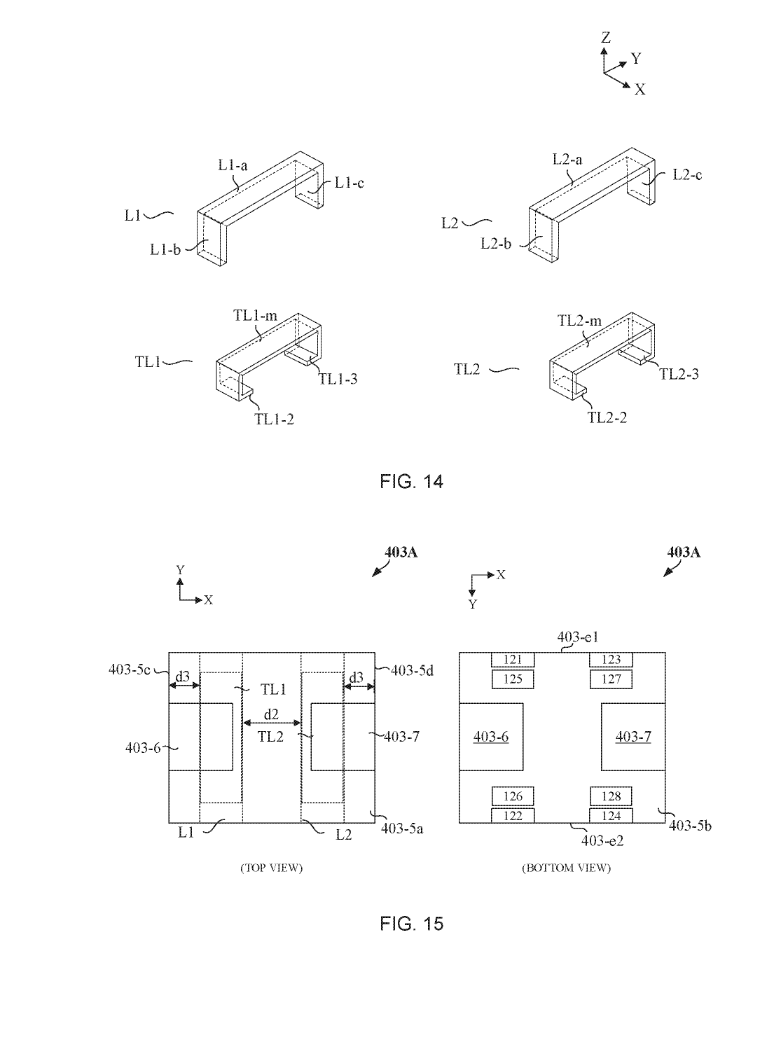

FIG. 14 shows a 3D perspective view of the primary windings L1 and L2 and the secondary windings TL1 and TL2 in accordance with an embodiment of the present invention. FIG. 15 shows, from left to right, a top view and a bottom view of the inductor assembly 403A in accordance with an embodiment of the present invention.

As shown in FIG. 14 and FIG. 15, the vertical sections L1-b and L1-c respectively form the first end 121 and the second end 122 of the primary winding L1 at the lower surface 403-5b of the inductor assembly 403A, and the vertical sections L2-b and L2-c respectively form the first end 123 and the second end 124 of the primary winding L2 at the lower surface 403-5b of the inductor assembly 403A. The secondary winding TL1 has a main body TL1-m and two portions TL1-2 and TL1-3, and the main body TL1-m connects the two portions TL1-2 and TL1-3. The secondary winding TL2 has a main body TL2-m and two portions TL2-2 and TL2-3, and the main body TL2-m connects the two portions TL2-2 and TL2-3. The main bodies TL1-m and TL2-m both have a top surface which is substantially parallel to the upper surface 403-5a of the inductor assembly 403A. The portions TL1-2 and TL1-3 respectively form the first end 125 and the second end 126 of the secondary winding TL1 at the lower surface 403-5b of the inductor assembly 403A, and the portions TL2-2 and TL2-3 respectively form the first end 127 and the second end 128 of the secondary winding TL2 at the lower surface 403-5b of the inductor assembly 403A. As shown in FIG. 15, the first ends 121, 123, 125, and 127 of the primary windings L1-L2 and the secondary windings TL1-TL2 are disposed close to a first edge 403-e1 of the inductor assembly 403, and the second ends 122, 124, 126, and 128 of the primary windings L1-L2 and the secondary windings TL1-TL2 are disposed close to a second edge 403-e2 of the inductor assembly 403, wherein the second edge 403-e2 is opposite to first edge 403-1e.

As mentioned before, the secondary winding TL1 is disposed under the horizontal section L1-a of the primary winding L1, and the secondary winding TL2 is disposed under the horizontal section L2-a of the primary winding L2. Therefore, as shown by dashed lines in the top view of the inductor assembly 403A of FIG. 15, a projection of the primary winding L1 on the upper surface 403-5a of the inductor assembly 403A (i.e., the XY plane) overlaps with at least partial of a projection of the secondary winding TL1 on the upper surface 403-5a of the inductor assembly 403A. Similarly, a projection of the primary winding L2 on the upper surface 403-5a of the inductor assembly 403A overlaps with at least partial of a projection of the secondary winding TL2 on the upper surface 403-5a of the inductor assembly 403A.

In the embodiments of the present disclosure, a distance d2 between the primary winding L1 and the primary winding L2 should be large enough to lower a coupling coefficient between the primary windings L1 and L2, so that interference between the two phases of switching circuits is reduced. The coupling coefficient between the primary windings L1 and L2 is smaller than 0.2, and more typically, smaller than 0.1. In one embodiment, a distance between the primary winding L1 and the primary winding L2 is larger than 2.5 times of a distance between the primary winding L1 and the side surface 403-5c and larger than 2.5 times of a distance between the primary winding L2 and the side surface 403-5d. In a further embodiment, the primary windings L1 and L2 are symmetrically placed, i.e., the distance between the primary winding L1 and the side surface 403-5c of the inductor assembly 403A is substantially equal to the distance between the primary winding L2 and the side surface 403-5c of the inductor assembly 403A, wherein the distance is labeled as d3. A ratio of the distance d2 and the distance d3 is larger than 2.5, i.e., d2/d3>2.5. In the embodiments of the present disclosure, “substantially equal” means an error of less than 10%.

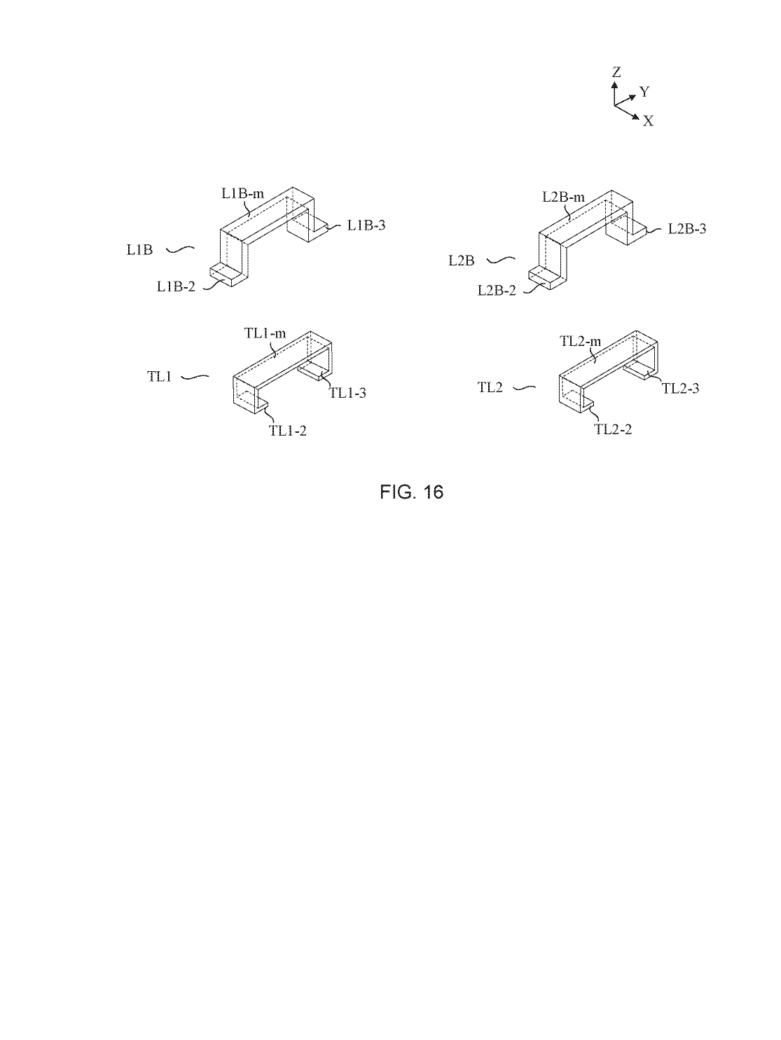

One with ordinary skills in the art should understand that the geometries of the second portions and third portions of the primary windings L1 and L2 and the secondary windings TL1 and TL2 are not limited by the example of FIG. 14. Other suitable shapes could also be implemented. For example, FIG. 16 shows a 3D perspective view of primary windings L1B and L2B and the secondary windings TL1 and TL2 in accordance with another embodiment of the present invention. In the embodiment of FIG. 16, the primary windings L1B and L2B have a shape which is different from that of the primary windings L1 and L2. In the example of FIG. 16, the primary windings L1 and L2 each have a main body L1B-m and L2B-m which are an “n” shape. The primary winding L1 further has two portions L1B-2 and L1B-3 which are connected via the main body L1B-m, and the primary winding L2 further has two portions L2B-2 and L2B-3 which are connected via the main body L2B-m. In the example of FIG. 16, the portion L1B-2 and the portion TL1-2 extend toward opposite directions, e.g., the portion L1B-2 of the primary winding L1B extends towards the side surface 403-5e of the inductor assembly 403A (not shown in FIG. 16) while the portion TL1-2 extends towards the side surface 403-5f of the inductor assembly 403A. In other words, the portion L1B-2 and the portion TL1-2 extend away from each other. The geometry of the primary winding L2B is same as that of the primary winding L1B and is not described here for brevity.

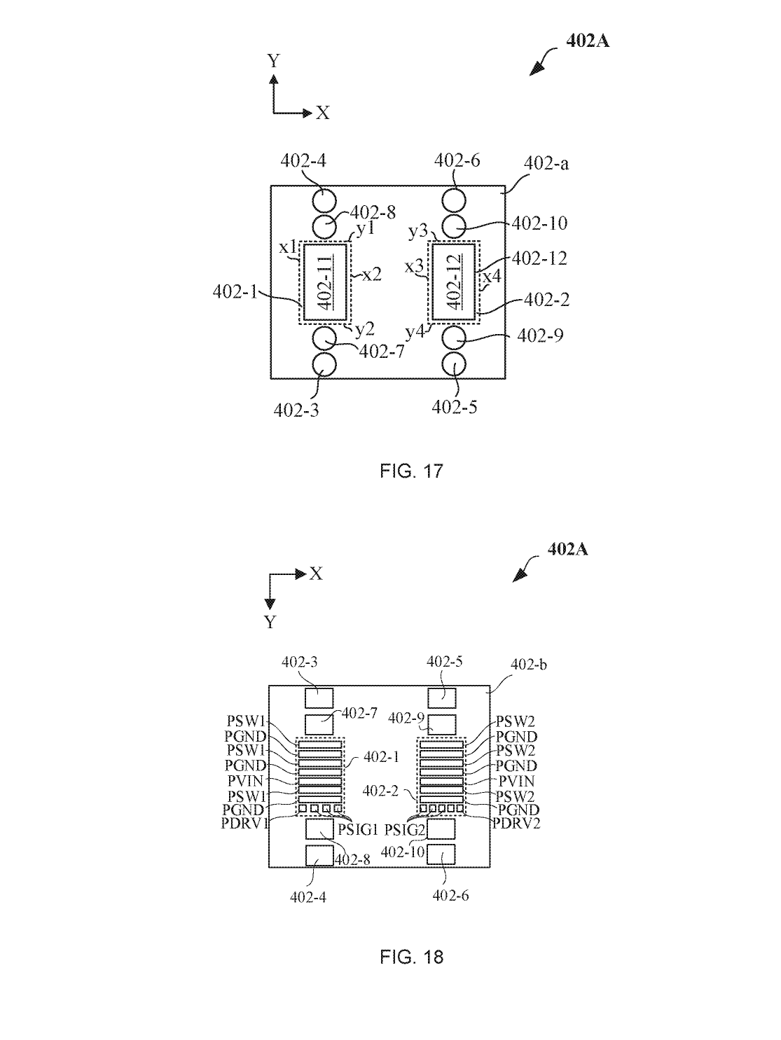

FIG. 17 shows a top view of the device substrate 402A in accordance with an embodiment of the present invention, i.e., the upper surface 402-a of the device substrate 402A. In the embodiment of FIG. 17, the die heat sink 402-11 covers partial of the power die 402-1, and the die heat sink 402-12 covers partial of the power die 402-2. As shown in FIG. 17, a top surface of the power die 402-1 has two long edges x1 and x2 which opposite each other, and two short edges y1 and y2 which opposite each other, and a top surface of the power die 302-2 has two long edges x3 and x4 which opposite each other, and two short edges y3 and y4 which opposite each other. In the embodiment of FIG. 17, the connecting pillars 402-3 and 402-7 are disposed adjacent to the short edge y2 of the power die 402-1, the connecting pillars 402-4 and 402-8 are disposed adjacent to the short edge y1 of the power die 402-1, the connecting pillars 402-5 and 402-9 are disposed adjacent to the short edge y4 of the power die 402-2, and the connecting pillars 402-6 and 402-10 are disposed adjacent to the short edge y3 of the power die 402-2. Each of the connecting pillars 402-3 through 402-10 has a first end exposed at the upper surface 402-a of the device substrate 402A.

When the bottom substrate 401A, the device substrate 402A and the inductor assembly 403A are assembled together, the ends of the windings L1, L2, TL1, and TL2 are attached to the corresponding connecting pillars via solder paste or conductive adhesive to form electrical connection between the windings L1, L2, TL1, and TL2 and the corresponding connecting pillars. To be specific, the first end 121 of the primary winding L1 is attached to the first end of the connecting pillar 402-3, so that the connecting pillar 402-3 is electrically connected to the switch node SW1 shown in FIG. 11. The first end 123 of the primary winding L2 is attached to the first end of the connecting pillar 402-5, so that the connecting pillar 403-5 is electrically connected to the switch node SW2 shown in FIG. 11. The second end 122 of the primary winding L1 is attached to the first end of the connecting pillar 402-4, and the second end 124 of the primary winding L2 is attached to the first end of the connecting pillar 402-6, so that the connecting pillars 402-4 and 402-6 are electrically connected to the output terminal 16 shown in FIG. 11. The first end 125 of the secondary winding TL1 is attached to the first end of the connecting pillar 402-7. The second end 126 of the secondary winding TL1 is attached to the first end of the connecting pillar 402-8. The first end 127 of the secondary winding TL2 is attached to the first end of the connecting pillar 402-9. The second end 128 of the secondary winding TL2 is attached to the first end of the connecting pillar 402-10. Since the second end 126 of the secondary winding TL1 and the first end 127 of the secondary winding TL2 are connected to form the trans-inductor loop, the connecting pillars 402-8 and 402-9 are electrically connected together. The connecting pillars 402-7 and 402-10 are electrically connected to the external compensation inductor or the secondary-side ground.

FIG. 18 shows a bottom view of the device substrate 402A in accordance with an embodiment of the present invention, i.e., the lower surface 402-b of the device substrate 402A. As shown in FIG. 18, each of the connecting pillars 402-3 through 402-10 has a second end exposed at the lower surface 402-b of the device substrate 402A. In the embodiment of FIG. 18, the power die 402-1 has a pin PDRV1 to receive the control signal PWM1 for controlling the switches M1 and M2 integrated in the power die 402-1, and the power die 402-2 has a pin PDRV2 to receive the control signal PWM2 for controlling the switches M1 and M2 integrated in the power die 402-2. The power die 402-1 has at least one pin PSW1 electrically connected to the switch node SW1 formed by the switch M1 and the switch M2. Similarly, the power die 402-2 has at least one pin PSW2 electrically connected to the switch node SW2 formed by the switch M1 and the switch M2. In the embodiment of FIG. 18, each of the power die 402-1 and the power die 402-2 further has at least one pin PVIN and at least one pin PGND. The pins PVIN is electrically connected to the first terminals of the switches M1, and the pins PGND is electrically connected to the second terminals of the switches M2. In the example of FIG. 18, the pins PVIN of the power die 402-1 and the power die 402-2 are electrically connected to the input terminal 16 to receive the input voltage Vin, and the pins PGND of the power die 402-1 and the power die 402-2 are electrically connected to the primary-side ground. In one embodiment, the power die 402-1 further has at least one pin PSIG1 for communication between the power die 402-1 and external circuits, and the power die 402-2 further has at least one pin PSIG2 for communication between the power die 402-2 and the external circuits. It is to be noted that the plurality of passive components 402-p are not shown in FIG. 18 for clarity. FIG. 18 shows a layout of the plurality of pins of the power die 402-1 and the plurality of pins of the power die 402-2. However, one with ordinary skills in the art should understand that the numbers and layout of the plurality of pins of the power die 402-1 and the plurality of pins of the power die 402-2 are not limited by the example of FIG. 18.

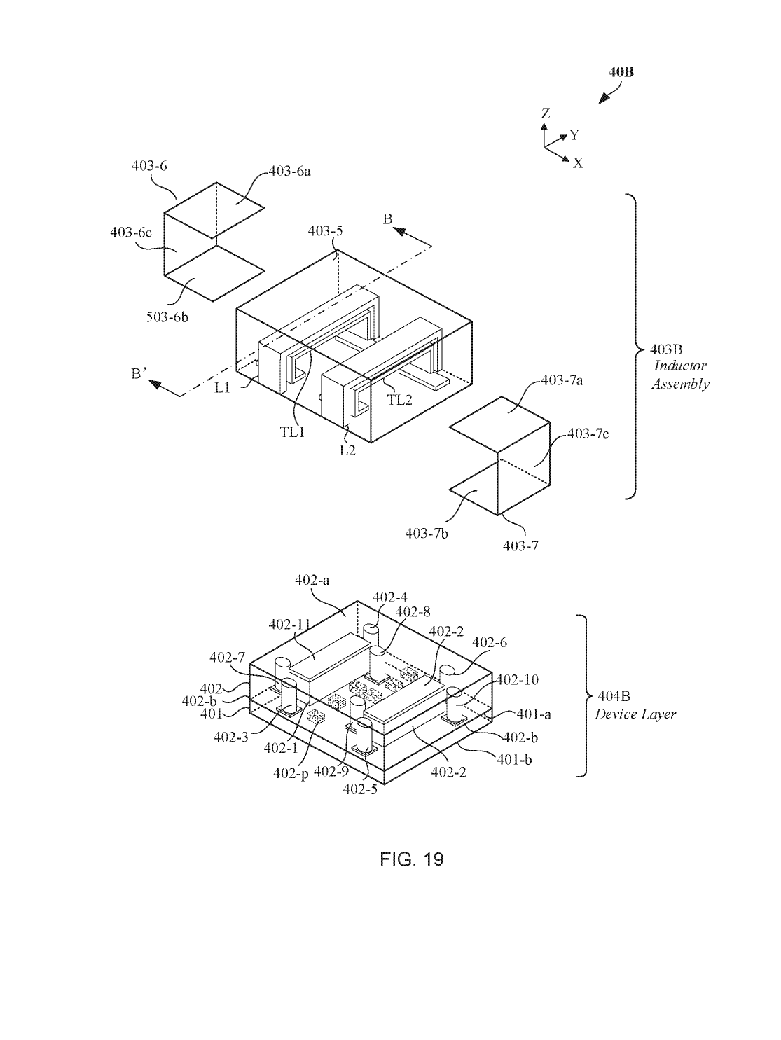

FIG. 19 shows a disassembled and perspective view of a power module 40B in accordance with another embodiment of the present invention implementing the circuit 40 of FIG. 11. The power module 40B has the same appearance as the power module 40A, which are not shown and described here for brevity.

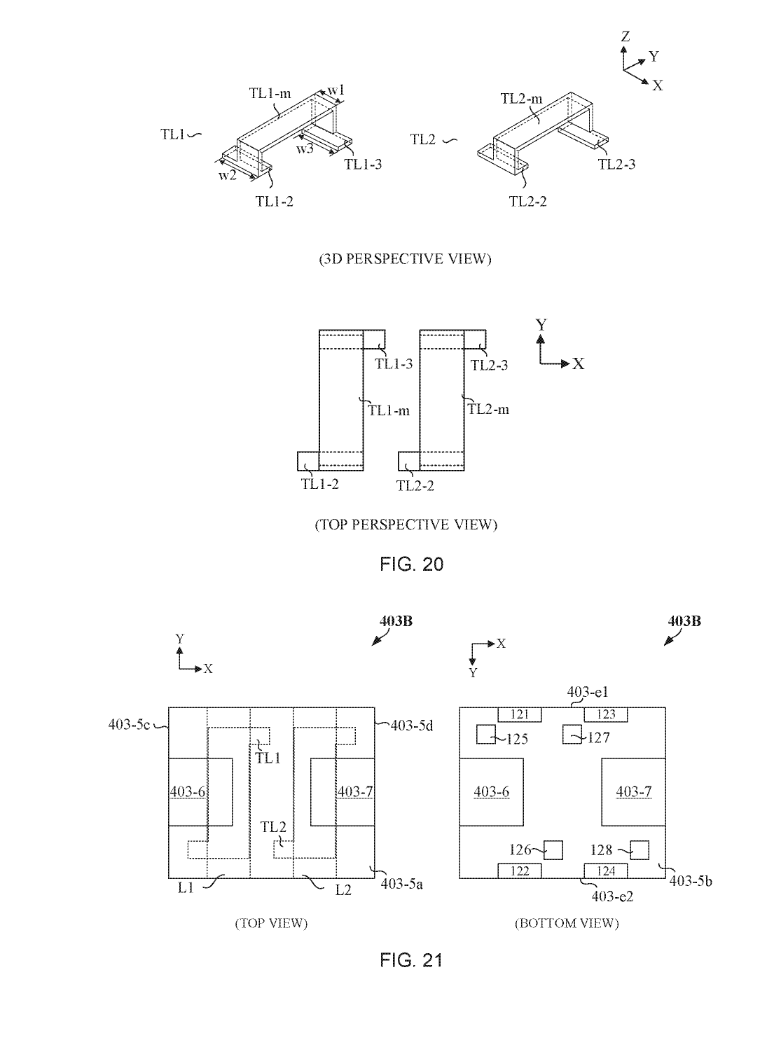

In the example of FIG. 19, the inductor assembly 403A has the two primary windings L1 and L2, the two secondary windings TL1 and TL2, the magnetic core 403-5, and the heat sink layers 403-6 and 403-7. The device layer 404B has the upper surface 402-a which is also the upper surface of the device substrate 402B, and has an opposite lower surface 401-b which is also a lower surface of the bottom substrate 401B. The device layer 404B comprises the power die 402-1, the power die 402-2, the connecting pillars 402-3 through 402-10, and the plurality of passive components 402-p. In the embodiment of FIG. 19, the primary windings L1 and L2 of the power module 40B have the same geometry as the primary windings L1 and L2 of the power module 40A. However, the secondary windings TL1 and TL2 have a geometry different from that of the secondary windings TL1 and TL2 of the power module 40A, and thus the layout of the connecting pillars 402-3 through 402-10 is also different from that of the power module 40A, which will be further discussed in FIG. 20-FIG. 23.

FIG. 20 shows, from top to bottom, a 3D perspective view of the secondary windings TL1 and TL2, and a top perspective view of the secondary windings TL1 and TL2 in accordance with an embodiment of the present invention. FIG. 21 shows a top perspective view and a bottom view of the inductor assembly 403B in accordance with an embodiment of the present invention. Because the secondary windings TL1 and TL2 possess identical geometry in the embodiment of FIG. 20, only the geometry of the winding TL1 is described herein in detail, and the geometry of the winding TL1 is omitted for brevity. As shown in FIG. 20, the main body TL1-m has a width w1 measured along the X-axis (i.e., measured along the first edge 403-e1 and the second edge 403-e2 of the inductor assembly 403, which are shown in FIG. 21), the portion TL1-2 has a width w2 measured along the X-axis, and the portion TL1-3 has a width w3 measured along the X-axis, wherein the width w2 and the width w3 are larger than the width w1. In one embodiment, the width w2 equals the width w3. As shown in the top perspective view of the secondary windings TL1 and TL2 shown in FIG. 20, the main body TL1-m of the secondary winding TL1 covers partial of the portions TL1-2 and TL1-3 of the secondary winding TL1. I.e., a projection of the main body TL1-m of the secondary winding TL1 on the lower surface 403-5b of the inductor assembly 403 (not shown in FIG. 20) partially overlaps with a projection of the portion TL1-2 of the winding TL1 on the lower surface 403-5b of the inductor assembly 403 and partially overlaps with a projection of the portion TL1-3 of the winding TL1 on the lower surface 403-5b of the inductor assembly 403. Similarly, a projection of the main body TL2-m of the secondary winding TL2 on the lower surface 403-5b of the inductor assembly 403 (not shown in FIG. 20) partially overlaps with a projection of the portion TL2-2 of the winding TL2 on the lower surface 403-5b of the inductor assembly 403 and partially overlaps with a projection of the portion TL2-3 of the winding TL2 on the lower surface 403-5b of the inductor assembly 403.

As shown by dashed lines in the top view of the inductor assembly 403B shown in FIG. 21, a projection of the primary winding L1 on the first surface 403-5a of the inductor assembly 403B (i.e., the XY plane) partially overlaps with a projection of the secondary winding TL1 on the first surface 403-5. Similarly, a projection of the primary winding L2 on the first surface 403-5a of the inductor assembly 403B partially overlaps with a projection of the secondary winding TL2 on the first surface 403-5a.

In the bottom view of the inductor assembly 403B shown in FIG. 21, the vertical sections L1-b and L1-c respectively form the first end 121 and the second end 122 of the primary winding L1 at the lower surface 403-5b of the inductor assembly 403B, and the vertical sections L2-b and L2-c respectively form the first end 123 and the second end 124 of the primary winding L2 at the lower surface 403-5b of the inductor assembly 403B. The main bodies TL1-m and TL2-m both have a top surface which is substantially parallel to the upper surface 403-5a of the inductor assembly 403B. The portions TL1-2 and TL1-3 extend to respectively form the first end 125 and the second end 126 of the secondary winding TL1 at the lower surface 403-5b of the inductor assembly 403B, and the portions TL2-2 and TL2-3 extend to respectively form the first end 127 and the second end 128 of the secondary winding TL2 at the lower surface 403-5b of the inductor assembly 403B.

In the embodiment of FIG. 21, an area of each of the ends 125, 126, 127, and 128 is smaller than a bottom surface area of the corresponding portion of the secondary windings TL1 and TL2. To be specific, the area of the first end 125 is smaller than the bottom surface area of the portion TL1-2 of the secondary winding TL1, the area of the second end 126 is smaller than the bottom surface area of the portion TL1-3 of the secondary winding TL1, the area of the first end 127 is smaller than the bottom surface area of the portion TL2-2 of the secondary winding TL2, and an area of the second end 128 is smaller than the bottom surface area of the portion TL2-3 of the secondary winding TL2. In other words, the ends 125, 126, 127, and 128 are formed on partial of the bottom surfaces of the corresponding portions of the secondary windings TL1 and TL2.

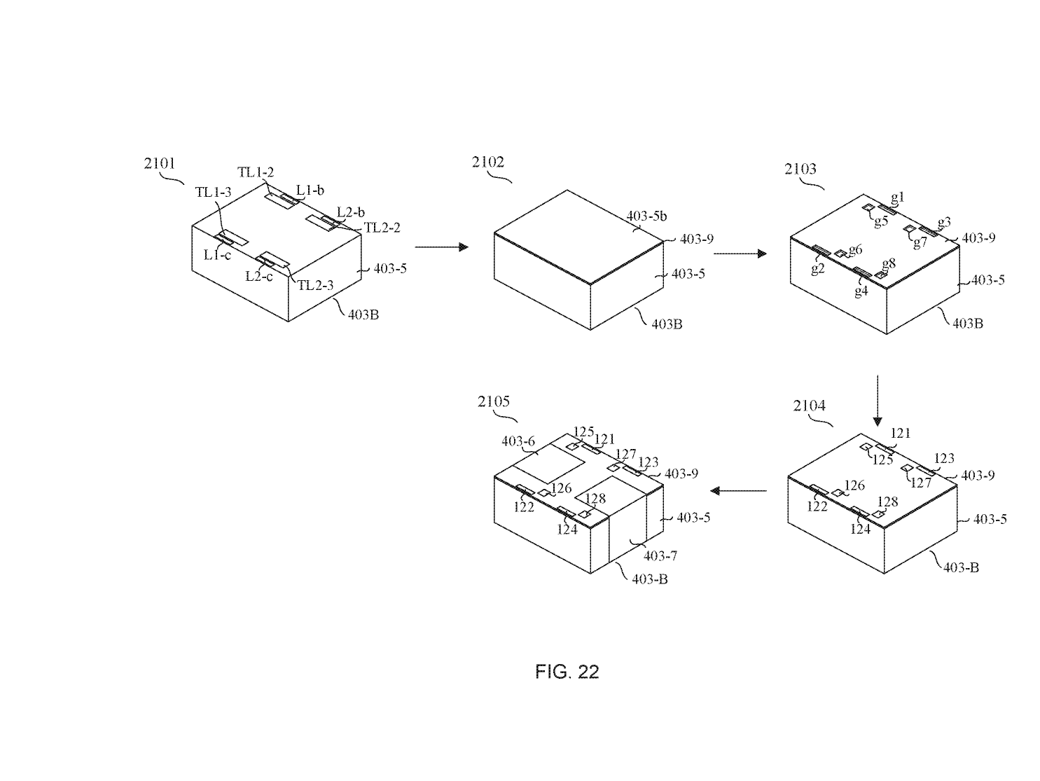

FIG. 22 illustrates a process for forming ends of the windings of the inductor assembly 403B in accordance with an embodiment of the present invention. As shown in step 2101, the primary windings L1 and L2, the secondary windings TL1 and TL2, and the magnetic core 403-5 are formed, and the vertical sections L1-b, L1-c, L2-b, and L2-c, and the portions TL1-2, TL1-3, TL2-2, and TL2-3 could be seen. In step 2102, insulating organic material is coated on the bottom surface of the magnetic core 403-5 to form an insulating organic material layer 403-9, and a surface of the insulating organic material layer 403-9 is also the second surface 403-5b of the inductor assembly 403B. It is to be noted that FIG. 22 is not drawn to scale. In real implementations the insulating organic material 403-9 may be very thin and could not be identified. In step 2103, cutting away the insulating organic material layer 403-9 in the positions corresponding to the vertical sections L1-b, L1-c, L2-b, and L2-c, and the portions TL1-2, TL1-3, TL2-2, and TL2-3 to form grooves g1-g8, so that at least partial of the bottom surfaces of the primary windings L1-L2 and the secondary windings TL1-TL2 are exposed. In the embodiment of FIG. 22, only partial of the insulating organic material layer 403-9 is removed in the areas corresponding to the portions TL1-2, TL1-3, TL2-2, and TL2-3, i.e., only partial of the bottom surfaces of the portions TL1-2, TL1-3, TL2-2, and TL2-3 are exposed after the step 2103. In other embodiments, the bottom surfaces of the portions TL1-2, TL1-3, TL2-2, and TL2-3 may also be fully exposed after the step of cutting the insulating organic material layer 403-9. In step 2104, electroplating metal material (e.g., a mix of Ni, Sn, and Cd) in the grooves g1-g8 to form the ends 121-128 of the windings. In step 2105, the heat sink layers 403-6 and 403-7 are formed on the surfaces of the inductor assembly 403B.

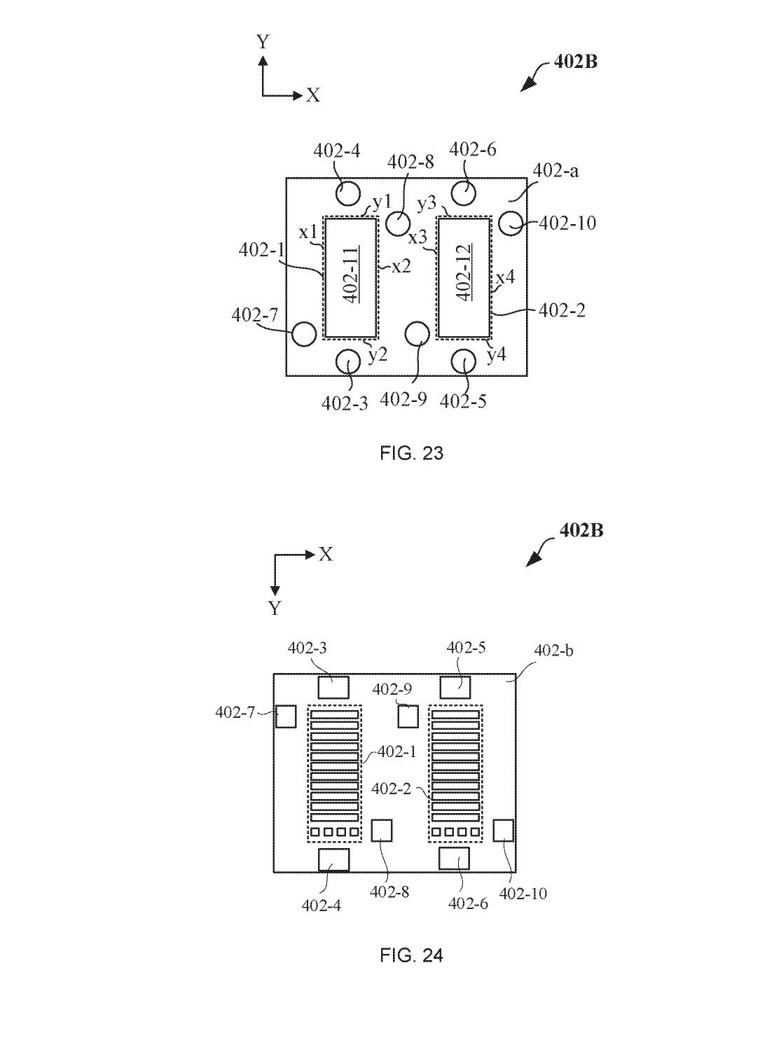

FIG. 23 shows a top view of the device substrate 402B in accordance with an embodiment of the present invention. To align with the locations of the ends 125-128, as shown in FIG. 23, the connecting pillar 402-7 is disposed adjacent to the long edge x1 of the power die 402-1, the connecting pillar 402-8 is disposed adjacent to the other long edge x2 of the power die 402-1, the connecting pillar 402-9 is disposed adjacent to the long edge x3 of the power die 402-2, and the connecting pillar 402-10 is disposed adjacent to the other long edge x4 of the power die 402-2. The connecting pillars 402-8 and 402-9 are disposed between the power die 402-1 and the power die 402-2. Similar to the device substrate 402B of the power module 40A, the connecting pillar 402-3 is disposed adjacent to the short edge y2 of the power die 402-1, the connecting pillar 402-4 is disposed adjacent to the short edge y1 of the power die 402-1, the connecting pillar 402-5 is disposed adjacent to the short edge y4 of the power die 402-2, the connecting pillar 402-5 is disposed adjacent to the short edge y3 of the power die 402-2. Accordingly, there are more space for the power die 402-1 and the power die 402-2, and a top surface area of each of the power die 402-1 and the power die 402-2 exceeds that of the power die 402-1 and the power die 402-2 in the power module 40A.

FIG. 24 shows a bottom view of the device substrate 402B in accordance with an embodiment of the present invention. As shown in FIG. 24, each of the connecting pillars 402-3 through 402-10 has the second end exposed at the second surface 402-b of the device substrate 402B. In the embodiment of FIG. 24, pin functions of the power die 402-1 and the power die 402-2 have been introduced in FIG. 18 and thus are not described here for brevity. It is to be noted that the plurality of passive components 402-p are not shown in FIG. 24 for clarity.

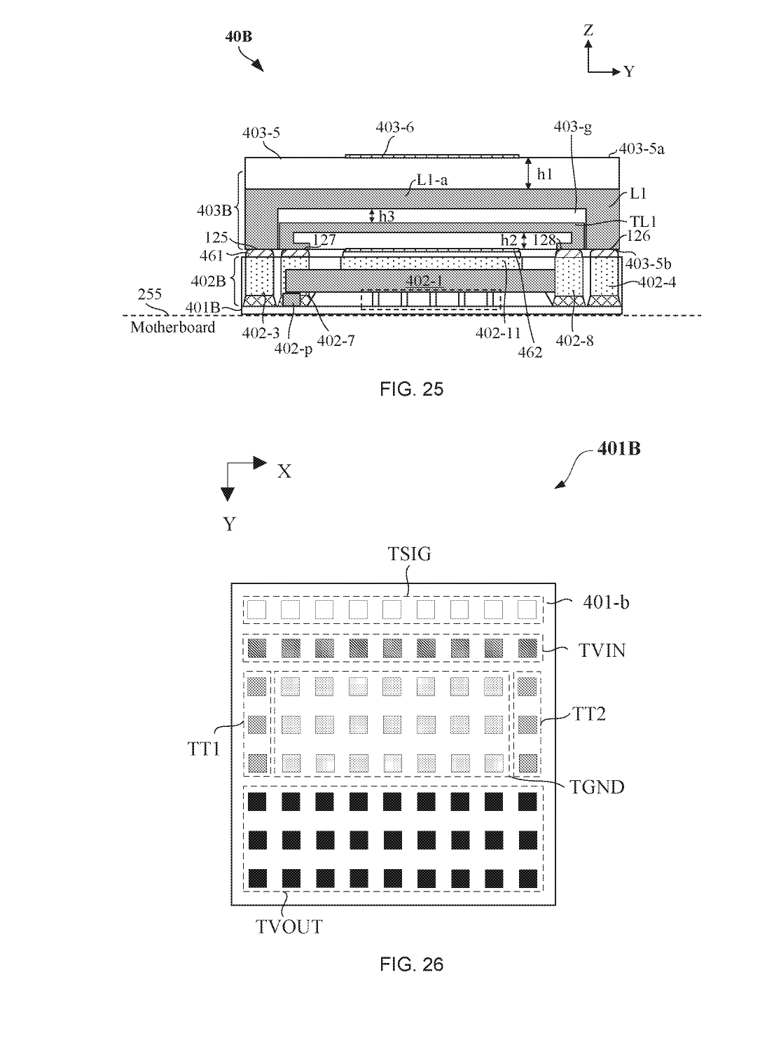

FIG. 25 shows a cross-sectional view illustrating the power module 40B taken along BB’ line of FIG. 19 in accordance with an embodiment of the present invention. Also shown in FIG. 25 is a representation of a motherboard 255 on which the power module 40B may be mounted. The motherboard 255 may be that of a device powered by the TLVR module 150. For example, the bottom substrate 401B may comprise a PCB. The bottom substrate 401B may include interconnect structures, such as vias, pins, or other conductive features, to route signals through and within the bottom substrate 401B. The motherboard 255 may support a controller for driving the switches of the power module 40B, a processor, memory, and other components of the device and/or a TLVR circuit that utilizes the power module 40B.

As shown in FIG. 25, the power die 402-1 has a first surface covered by the die heat sink 402-11 and a second surface opposite its first surface. The power die 402-1 has the plurality of pins (marked in a box with dashed line) exposed at its second surface as shown in FIG. 25. In one embodiment, the power die 402-1 is soldered to the device substrate 402B via the plurality of pins. Similarly, the power die 402-2 is soldered to the device substrate 402B also via a plurality of pins, which is not shown in FIG. 25. In some embodiments, the plurality of pins of the power die 402-1 and the power die 402-2 may comprise pads, bumps, ball grid arrays (BGA), or land grid arrays (LGA), etc. In one embodiment, the heat sink layer 403-6 is attached to the surface of the die heat sink 402-11 directly or via a heat conductive contact 462 as shown in the example of FIG. 25. Similarly, the heat sink layer 403-7 is attached to the surface of the die heat sink 402-12 directly or via the heat conductive contact 462 (not shown in FIG. 25). In some embodiments, the heat conductive contact 462 may comprise thermal glue, thermal paste, and thermal grease type or thermal putty type of dispensable materials, etc.

In the embodiment of FIG. 25, the primary winding L1 and the secondary winding TL1 are soldered to the device substrate 402B. To be specific, the first end 121 of the primary winding L1 is attached to the first end of the connecting pillar 402-3 via solder paste 461 to form electrical connection between the first end 121 of the primary winding L1 and the connecting pillar 402-3, and the second end 122 of the primary winding L1 is attached to the first end of the connecting pillar 402-4 via the solder paste 461 to form electrical connection between the second end 122 of the primary winding L1 and the connecting pillar 402-4. Similarly, the first end 125 of the secondary winding TL1 is attached to the first end of the connecting pillar 402-7 via the solder paste 561 to form electrical connection between the first end 125 of the secondary winding TL1 and the connecting pillar 402-7, and the second end 126 of the secondary winding TL1 is attached to the first end of the connecting pillar 402-8 via the solder paste 461 to form electrical connection between the second end 126 of the secondary winding TL1 and the connecting pillar 402-8. In one embodiment, the connecting pillars 402-3 through 402-10 are also soldered to the bottom substrate 401B.

In the embodiment of FIG. 25, to provide a symmetrical magnetic path and thus increase the inductance of the primary windings L1 and L2, when the magnetic core 403-5 is formed from a single type of magnetic material, the magnetic material above the horizontal section L1-a of the primary winding L1 has a height that is substantially equal to a sum of a height of the magnetic material between the horizontal section L1-a of the primary winding L1 and the horizontal section of the secondary winding TL1 and a height of the magnetic material below the horizontal section of the secondary winding TL1. a symmetrical magnetic path Specifically, in one example, the magnetic core 403-5 is constructed as a single piece without an air gap, so that the magnetic material is filled between the horizontal section L1-a of the primary winding L1 and the horizontal section of the secondary winding TL1 with a height h3 measured from a lower surface of the horizontal section L1-a of the primary winding L1 to a top surface of the horizontal section of the secondary winding TL1. Also, the magnetic material above the horizontal section L1-a of the primary winding L1 has a height h1 measured from the top surface 403-5a of the magnetic core 403-5 to the top surface of the primary winding L1, and the magnetic material below the horizontal section of the secondary winding TL1 has a height h2 measured from the top surface of the horizontal section of the secondary winding TL1 to the bottom surface 403-5b of the magnetic core 403-5. Consequently, the height h1 is substantially equal to a sum of the height h2 and the height h3. In an alternative embodiment, if there is an air gap between the primary winding L1 and the secondary winding TL1 or non-magnetic material is present in this region, the height h1 may be substantially equal to the height h2. In the embodiments of the present disclosure, “substantially equal” means an error of less than 10%.

In one embodiment, the height h3 also stands for a distance between the primary winding L1 and the secondary winding TL1. The height h3 is controlled to make a coupling coefficient between the primary winding L1 and the secondary winding TL1 larger than 0.7, and more typically, in a range of 0.7-0.95. Similarly, a coupling coefficient between the primary winding L2 and the secondary winding TL2 is also kept larger than 0.7, and more typically, in the range of 0.7-0.95.

FIG. 26 shows a bottom view of the bottom substrate 401B in accordance with an embodiment of the present invention. As shown in FIG. 26, the power module 40B further has a plurality of pads disposed on the second surface 401-b of the bottom substrate 401B for electrically connecting the power module 40B to external circuits. In the embodiment of FIG. 26, The plurality of pads on the second surface 401-b of the bottom substrate 401B comprise a plurality of pads TVIN electrically connected to the input node 15 to receive the input voltage Vin, a plurality of pads TGND electrically connected to the reference ground, a plurality of pads TVOUT electrically connected to the output node 16 to provide the output voltage Vout, a plurality of pads TSIG for signal transmission between the power dies 402-1 and 402-2 and the external circuits, a plurality of pads TT1 electrically connected to the terminal T1-1 of the secondary winding TL1, and a plurality of pads TT2 electrically connected to the terminal T2-2 of the secondary winding TL2. The plurality of pads TT1 and the plurality of pads TT2 are capable of electrically connecting to either the reference ground or the compensation external inductor. FIG. 26 shows a layout of the plurality of pads on the second surface 401-b of the bottom substrate 401B. However, one with ordinary skills in the art should understand that the numbers and layout of the plurality of pads are not limited by the example of FIG. 26.

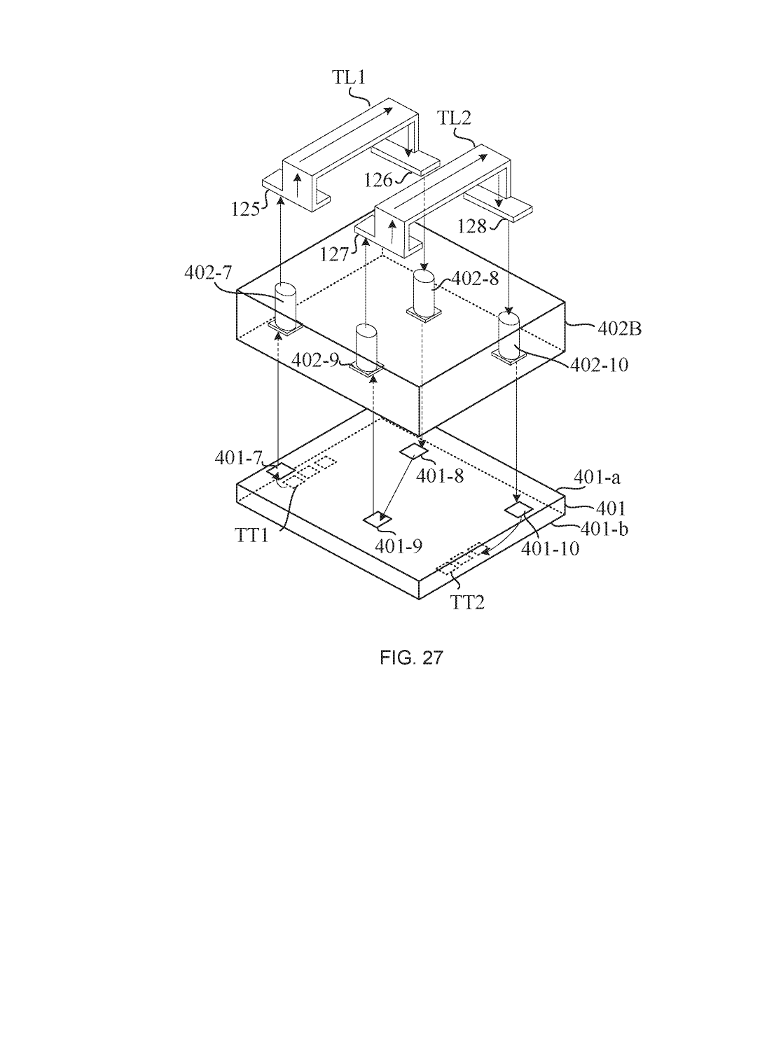

FIG. 27 schematically shows electrical connection paths of the secondary windings TL1 and TL2. For clarity, FIG. 27 only shows the secondary windings TL1 and TL2, the connecting pillars 402-7 through 402-10 in the device substrate 402B, pads 401-7 through 401-10 on the first surface 401-a of the bottom substrate 401B, and the plurality of pads TT1 and the plurality of pads TT2 on the second surface 401-b of the bottom substrate 401B. As shown in FIG. 27, the arrows show the electrical connection paths of the secondary windings TL1 and TL2, which also denote current paths of the trans-inductor loop while the power module 40B is operating.

In one embodiment, while the power module 40B is operating, a current in the trans-inductor loop is first conducted from the plurality of pads TT1 on the second surface 401-b of the bottom substrate 401B to the pad 401-7 on the first surface 401-a of the bottom substrate 401B, e.g., via conductive traces in the bottom substrate 401B, then conducted to the connecting pillar 402-7 in the device substrate 402B to reach the first end 125 of the secondary winding TL1 via the connecting pillar 402-7. Then the current flows through the secondary winding TL1 to reach the second end 126 of the secondary winding TL1, and is further conducted to the connecting pillar 402-8, and then conducted to the pad 401-8 via the connecting pillar 402-8. As shown in FIG. 27, the pads 401-8 and 401-9 are electrically connected in the bottom substrate 401B, e.g., via conductive traces in the bottom substrate 401B. The current is further conducted from the pad 401-9 to the connecting pillar 402-9 and reaches the first end 127 of the secondary winding TL2 via the connecting pillar 402-9, then flows through the secondary winding TL1 to reach the second end 128 of the secondary winding TL2, and is further conducted to the connecting pillar 402-10, and then conducted to the pad 401-10 via the connecting pillar 402-10. The current is then conducted to the plurality of pads TT1 on the second surface 401-b of the bottom substrate 401B, e.g., via conductive traces in the bottom substrate 401B.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power module, comprising:
a device layer having a first surface and an opposite second surface, wherein the device layer comprises a first power die and a second power die, and each of the first power die and the second power die has a pair of switches electrically connected in series; and
an inductor assembly having a first surface and an opposite second surface, wherein the second surface of the inductor assembly is attached to the first surface of the device layer, the inductor assembly comprising:
a magnetic core; and
a first winding, a second winding, a third winding, and a fourth winding which are at least partially embedded within the magnetic core, wherein each of the first winding, the second winding, the third winding, and the fourth winding has a first end and a second end exposed at the second surface of the inductor assembly; wherein
the third winding and the first winding are magnetically coupled through at least partial of the magnetic core to form a first transformer, the fourth winding and the second winding are magnetically coupled through at least partial of the magnetic core to form a second transformer, and the third winding and the fourth winding are electrically connected in series; and wherein
each of the first winding and the second winding comprises a horizontal section substantially parallel to the first surface of the inductor assembly, and the third winding and the fourth winding are respectively positioned under the horizontal sections of the first winding and the second winding.

2. The power module of claim 1, wherein the device layer further comprises:
a first die heat sink covering at least partial of the first power die; and
a second die heat sink covering at least partial of the second power die; wherein
each of the first die heat sink and the second die heat sink has a surface exposed at the first surface of the device layer.

3. The power module of claim 2, wherein:
the inductor assembly further comprises a first heat sink layer and a second heat sink layer wrapping at least partial of the magnetic core; and wherein
the first heat sink layer has a portion attached to the first surface of the device layer covering at least partial of the first die heat sink, and the second heat sink layer has a portion attached to the first surface of the device layer covering at least partial of the second die heat sink.

4. The power module of claim 1, wherein the inductor assembly further comprises:
a first heat sink layer wrapping at least partial of the inductor assembly, wherein the first heat sink layer has a first portion partially covering the second surface of the inductor assembly, and a second portion partially covering a third surface of the inductor assembly, and wherein the third surface of the inductor assembly is perpendicular to the first surface and the second surface of the inductor assembly, and is parallel to the horizontal section of the first winding; and
a second heat sink layer wrapping at least partial of the inductor assembly, wherein the second heat sink layer has a first portion partially covering the second surface of the inductor assembly, and a second portion partially covering a fourth surface of the inductor assembly, and wherein the fourth surface of the inductor assembly is perpendicular to the first surface and the second surface of the inductor assembly, and is parallel to the horizontal section of the second winding; wherein
the third surface and the fourth surface of the inductor assembly are opposite.

5. The power module of claim 1, wherein:
the switches of the first power die have a first common node electrically connected to the first end of the first winding, and the switches of the second power die have a second common node electrically connected to the first end of the second winding; and
the second end of the first winding and the second end of the second winding are electrically connected together to provide an output voltage.

6. The power module of claim 1, wherein each of the third winding and the fourth winding has an “n”-shape main body, a first portion, and a second portion, wherein the main body connects the first portion and the second portion, and wherein:
the first portion of the third winding forms the first end of the third winding on the second surface of the inductor assembly, and the second portion of the third winding forms the second end of the third winding on the second surface of the inductor assembly; and
the first portion of the fourth winding forms the first end of the fourth winding on the second surface of the inductor assembly, and the second portion of the fourth winding forms the second end of the fourth winding on the second surface of the inductor assembly.

7. The power module of claim 6, wherein:
a projection of the main body of the third winding on the second surface of the inductor assembly partially overlaps with a projection of the first portion of the third winding on the second surface of the inductor assembly and partially overlaps with a projection of the second portion of the third winding on the second surface of the inductor assembly; and
a projection of the main body of the fourth winding on the second surface of the inductor assembly partially overlaps with a projection of the first portion of the fourth winding on the second surface of the inductor assembly and partially overlaps with a projection of the second portion of the fourth winding on the second surface of the inductor assembly.

8. The power module of claim 1, wherein the device layer further comprises:
a first connecting pillar having a surface attached to the first end of the first winding, wherein the first connecting pillar is electrically connected to the first power die;
a second connecting pillar having a surface attached to the second end of the first winding, wherein the second connecting pillar is electrically connected to a first pad on the second surface of the device layer to provide an output voltage;
a third connecting pillar having a surface attached to the first end of the second winding, wherein the third connecting pillar is electrically connected to the second power die;
a fourth connecting pillar having a surface attached to the second end of the second winding, wherein the fourth connecting pillar is electrically connected to the first pad on the second surface of the device layer to provide the output voltage;
a fifth connecting pillar having a surface attached to the first end of the third winding, wherein the fifth connecting pillar is electrically connected to a second pad on the second surface of the device layer;
a sixth connecting pillar having a surface attached to the second end of the third winding;
a seventh connecting pillar having a surface attached to the first end of the fourth winding, wherein the sixth connecting pillar and the seventh connecting pillar are electrically connected together; and
an eighth connecting pillar having a surface attached to the second end of the fourth winding, wherein the eighth connecting pillar is electrically connected to a third pad on the second surface of the device layer.

9. The power module of claim 8, wherein:
the sixth connecting pillar and the seventh connecting pillar are disposed between the first power die and the second power die.

10. The power module of claim 1, wherein:
a coupling coefficient between the first winding and the second winding is smaller than 0.2.

11. The power module of claim 1, wherein:
the inductor assembly further comprises a third surface and an opposite fourth surface which are perpendicular to the first surface and the second surface of the inductor assembly, wherein the third surface is adjacent to the first winding, and the fourth surface is adjacent to the second winding; and wherein
a distance between the first winding and the second winding is larger than 2.5 times of a distance between the first winding and the third surface and larger than 2.5 times of a distance between the second winding and the fourth surface.

12. A power module, comprising:
a device layer having a first surface and an opposite second surface, wherein the device layer comprises a first pair of switches electrically connected in series and a second pair of switches electrically connected in series; and
an inductor assembly having a first surface and an opposite second surface, wherein the second surface of the inductor assembly is attached to the first surface of the device layer, the inductor assembly comprising:
a magnetic core;
a first heat sink layer and a second heat sink layer wrapping at least partial of the magnetic core; and
a first winding, a second winding, a third winding, and a fourth winding which are at least partially embedded within the magnetic core, each winding having a first end and a second end exposed at the second surface of the inductor assembly, wherein the first end of the first winding is electrically connected to a common node of the first pair of switches, and the first end of the second winding is electrically connected to a common node of the second pair of switches; wherein
the third winding and the first winding are magnetically coupled through at least partial of the magnetic core to form a first transformer, the fourth winding and the second winding are magnetically coupled through at least partial of the magnetic core to form a second transformer, and the third winding and the fourth winding are electrically connected in series; and wherein
the first winding surrounds the third winding, and the second winding surrounds the fourth winding.

13. The power module of claim 12, wherein:
each of the first winding and the second winding comprises a horizontal section substantially parallel to the first surface of the inductor assembly and two vertical sections, wherein the horizontal section connects the two vertical sections; and wherein
the third winding is disposed under the horizontal section of the first winding and between the two vertical sections of the third winding, and the fourth winding is disposed under the horizontal section of the second winding and between the two vertical sections of the second winding.

14. The power module of claim 12, wherein each of the third winding and the fourth winding has a first portion forming the first end, a second portion forming the second end, and an “n”-shape main body connecting the first portion and the second portion, wherein:
the first ends of the first winding, the second winding, the third winding, and the fourth winding are disposed close to a first edge of the inductor assembly, and the second ends of the first winding, the second winding, the third winding, and the fourth winding are disposed close to a second edge of the inductor assembly which is opposite to the first edge; and wherein
for each of the third winding and the fourth winding, a first width of the main body is smaller than a second width of the first portion and is smaller than a third width of the second portion, wherein the first width, the second width, and the third width are measured along the first edge.

15. The power module of claim 14, wherein the device layer further comprises:
a first connecting pillar having a surface attached to the second end of the third winding; and
a second connecting pillar having a surface attached to the first end of the fourth winding, wherein the sixth connecting pillar and the seventh connecting pillar are electrically connected together; wherein
the first connecting pillar and the second connecting pillar are electrically connected together.

16. An inductor assembly, comprising:
a magnetic core; and
a first winding, a second winding, a third winding, and a fourth winding which are at least partially embedded within the magnetic core, wherein each of the first winding, the second winding, the third winding, and the fourth winding has a first end and a second end exposed at a bottom surface of the inductor assembly; wherein
the first winding and the third winding are respectively configured as a primary winding and a secondary winding of a first transformer, and the second winding and the fourth winding are respectively configured as a primary winding and a secondary winding of a second transformer; and wherein
each of the first winding and the second winding comprises a horizontal section substantially parallel to the bottom surface of the inductor assembly, and the third winding and the fourth winding are respectively disposed under the horizontal sections of the first winding and the second winding.

17. The inductor assembly of claim 16, wherein:
a coupling coefficient between the first winding and the second winding is smaller than 0.2.

18. The inductor assembly of claim 16, wherein:
the first winding surrounds the third winding, and the second winding surrounds the fourth winding; and wherein
a coupling coefficient between the first winding and the third winding is larger than 0.7, and a coupling coefficient between the second winding and the fourth winding is larger than 0.7.

19. The inductor assembly of claim 16, wherein each of the third winding and the fourth winding has a first portion forming the first end, a second portion forming the second end, and an “n”-shape main body connecting the first portion and the second portion, wherein:
the first ends of the first winding, the second winding, the third winding, and the fourth winding are disposed close to a first edge of the inductor assembly, and the second ends of the first winding, the second winding, the third winding, and the fourth winding are disposed close to a second edge of the inductor assembly which is opposite to the first edge; and wherein
for each of the third winding and the fourth winding, a first width of the main body is smaller than a second width of the first portion and is smaller than a third width of the second portion, wherein the first width, the second width, and the third width are measured along the first edge.

20. The inductor assembly of claim 19, wherein:
a projection of the main body of the third winding on the bottom surface of the inductor assembly partially overlaps with a projection of the first portion of the third winding on the bottom surface of the inductor assembly and partially overlaps with a projection of the second portion of the third winding on the bottom surface of the inductor assembly; and
a projection of the main body of the fourth winding on the bottom surface of the inductor assembly partially overlaps with a projection of the first portion of the fourth winding on the bottom surface of the inductor assembly and a projection of the second portion of the fourth winding on the bottom surface of the inductor assembly.
